(19) United States
(12) Patent Application Publication
(10) Pub. No.: US 2026/0313247 A1
(43) Pub. Date: Oct. 8, 2026

(54) IMAGE SENSOR INCLUDING PIXEL CIRCUIT, METHOD OF OPERATING IMAGE SENSOR, AND ELECTRONIC DEVICE INCLUDING IMAGE SENSOR

(71) Applicant: Samsung Electronics Co., Ltd., Suwon-si (KR)

(72) Inventors: WOOSEOK CHOI, Suwon-si (KR); EUN SUB SHIM, Suwon-si (KR); Jaeho LEE, Suwon-si (KR); JAESEONG YU, Suwon-si (KR); Hyunwoo KIM, Suwon-si (KR)

(21) Appl. No.: 19/413,880

(22) Filed: Dec. 9, 2025

(30) Foreign Application Priority Data
Apr. 2, 2025 (KR) 10-2025-0042872

(51) Int. Cl. H04N 25/13; H04N 25/40; H04N 25/78

(52) U.S. Cl. CPC H04N 25/134; H04N 25/40; H04N 25/78

(57) ABSTRACT

An image sensor includes a pixel array including a first pixel including first to fourth sub-pixels and a second pixel including fifth to eighth sub-pixels, and a row driver configured to provide first to fourth transfer gate signals to the first to fourth sub-pixels via first to fourth transmission lines. The first to fourth sub-pixels are configured to share a first-color color filter and a first microlens, the fifth to eighth sub-pixels are configured to share a second-color color filter and a second microlens, the first sub-pixel and the sixth sub-pixel are configured to receive the first transfer gate signal, the second sub-pixel and the fifth sub-pixel are configured to receive the second transfer gate signal, the third sub-pixel and the seventh sub-pixels are configured to receive the third transfer gate signal, and the fourth sub-pixel and the eighth sub-pixel are configured to receive the fourth transfer gate signal.

### CROSS-REFERENCE TO RELATED APPLICATIONS

This application claims priority under 35 U.S.C. § 119 to Korean Patent Application No. 10-2025-0042872 filed on Apr. 02, 2025 in the Korean Intellectual Property Office, the disclosure of which is incorporated by reference herein in their entirety.

### BACKGROUND

Embodiments of a present disclosure described herein relate to an image sensor, and more particularly, to an image sensor including a pixel, a method of operating the same, and an electronic device including the same.

The image sensor may receive light corresponding to an external scene, generate an electrical signal based on the received light, and process the electrical signal to generate image data. A display device may visually display the external scene sensed by the image sensor based on the image data. A quality level of the external scene displayed by the display device may depend on various factors such as resolution, illumination environment, focus, and the like.

Recently, a high-quality level of the image data is required. Accordingly, in order to provide various functions or operations such as high resolution, wide illumination range, auto-focus, etc., pixels of the image sensor may be disposed, a disposition of wire lines electrically connected to the pixels may be optimized, or a method of operating the pixels may be optimized.

### SUMMARY

Embodiments of the present disclosure provide an image sensor including a pixel, a method for operating the same, and an electronic device including the same are provided.

According to an embodiment, an image sensor comprising a pixel array including a first pixel comprising first to fourth sub-pixels arranged in a clockwise direction and a second pixel comprising fifth to eighth sub-pixels arranged in the clockwise direction, and a row driver configured to provide first to fourth transfer gate signals to the first to fourth sub-pixels via first to fourth transmission lines, wherein the first to fourth sub-pixels are configured to share a first-color color filter and a first microlens, wherein the fifth to eighth sub-pixels are configured to share a second-color color filter and a second microlens, wherein the first-color is the same as the second-color, wherein the first sub-pixel and the sixth sub-pixel are configured to receive the first transfer gate signal via the first transmission line, wherein the second sub-pixel and the fifth sub-pixel are configured to receive the second transfer gate signal via the second transmission line, wherein the third sub-pixel and the seventh sub-pixels are configured to receive the third transfer gate signal via the third transmission line, and wherein the fourth sub-pixel and the eighth sub-pixel are configured to receive the fourth transfer gate signal via the fourth transmission line

According to an embodiment, an image sensor comprising a pixel array including a first pixel comprising first and second sub-pixels and a second pixel comprising third and fourth sub-pixels, and a row driver configured to provide first and second transfer gate signals to the first to fourth sub-pixels via first and second transmission lines, wherein the first and second sub-pixels are configured to share a first-color color filter and a first microlens, wherein the third and fourth sub-pixels are configured to share a second-color color filter and a second microlens, wherein the first-color is the same as the second-color, wherein the first sub-pixel and the fourth sub-pixel are configured to receive the first transfer gate signal via the first transmission line, wherein the second sub-pixel and the third sub-pixel are configured to receive the second transfer gate signal via the second transmission line, and wherein the first to fourth sub-pixels are sequentially arranged in a first row.

According to an embodiment, an image sensor comprising a pixel array including a first pixel comprising first and second sub-pixels, a second pixel comprising third and fourth sub-pixels, and a third pixel comprising fifth and sixth sub-pixels, and a row driver configured to provide first to third transfer gate signals to the first to fourth sub-pixels via first to third transmission lines, wherein the first and second sub-pixels are configured to share a first green color filter and a first microlens, wherein the third and fourth sub-pixels are configured to share a second green color filter and a second microlens, wherein the fifth and sixth sub-pixels are configured to share a third green color filter and a third microlens, wherein the first sub-pixel and the fourth sub-pixel are configured to receive the first transfer gate signal via the first transmission line, wherein the second sub-pixel and the third sub-pixel are configured to receive the second transfer gate signal via the second transmission line, wherein the first to fourth sub-pixels are sequentially arranged in a first row, wherein the first sub-pixel is directly adjacent to the fifth sub-pixel in a first column, and wherein each of the first sub-pixel and the fifth sub-pixel are disposed on a left side of each of the first pixel and the third pixel in a plan view.

According to an embodiment, an image sensor comprises a pixel array including a first pixel group and a second pixel group, wherein the first pixel group includes a first pixel including a first, a second, a third, and a fourth sub-pixel arranged in a first direction and a second direction perpendicular to the first direction, and the second pixel group includes a second pixel including a fifth, a sixth, a seventh, and an eighth sub-pixel arranged at positions corresponding to the first, the second, the third, and the fourth sub-pixel; and a row driver connected to the first and the sixth sub-pixels via a first transmission line, the row driver connected to the second and the fifth sub-pixels via a second transmission line, the row driver connected to the third and the eighth sub-pixels via a third transmission line, and the row driver connected to the fourth and the seventh sub-pixels via a fourth transmission line, wherein the row driver is configured to provide a first and a second transfer gate signal to the first and the third transmission lines, respectively, wherein the first pixel is configured to generate a first output signal based on the first and the second transfer gate signals, and wherein the second pixel is configured to generate a second output signal based on the first and the second transfer gate signals..

According to an embodiment, an image sensor includes a first pixel, a second pixel, and a row driver. A method of operating the image sensor comprises providing, by the row driver, a first and a second transfer gate signal to each of the first and the second pixels; generating, by the first pixel, a first output signal based on the first and the second transfer gate signals; and generating, by the second pixel, a second output signal based on the first and the second transfer gate signals, wherein the first pixel includes a first, a second, a third, and a fourth sub-pixel arranged in a first direction and a second direction perpendicular to the first direction, wherein the second pixel includes a fifth, a sixth, a seventh, and an eighth sub-pixel arranged at positions corresponding to the first, the second, the third, and the fourth sub-pixels, wherein the row driver is connected to the first and the sixth sub-pixels via a first transmission line, the row driver is connected to the second and the fifth sub-pixels via a second transmission line, the row driver is connected to the third and the eighth sub-pixels via a third transmission line, and the row driver is connected to the fourth and the seventh sub-pixels via a fourth transmission line, wherein the first transfer gate signal is provided via the first transmission line, and wherein the second transfer gate signal is provided via the third transmission line.

According to an embodiment, an electronic device comprises an image sensor configured to generate image data; a memory device configured to store the image data; and a processor configured to manage the image data, wherein the image sensor includes: a pixel array including a first pixel group and a second pixel group, wherein the first pixel group includes a first pixel including a first, a second, a third, and a fourth sub-pixel arranged in a first direction and a second direction perpendicular to the first direction, and the second pixel group includes a second pixel including a fifth, a sixth, a seventh, and an eighth sub-pixel arranged at positions corresponding to the first, the second, the third, and the fourth sub-pixels; a row driver connected to the first and the sixth sub-pixels via a first transmission line, the row driver connected to the second and the fifth sub-pixels via a second transmission line, the row driver connected to the third and the eighth sub-pixels via a third transmission line, and the row driver connected to the fourth and the seventh sub-pixels via a fourth transmission line; a signal reading circuit connected to the pixel array; and a signal processor connected to the signal reading circuit, wherein the row driver is configured to provide a first and a second transfer gate signals to the first and the third transmission lines, respectively, wherein the first pixel is configured to generate a first output signal based on the first and the second transfer gate signals, wherein the second pixel is configured to generate a second output signal based on the first and the second transfer gate signals, wherein the signal reading circuit is configured to generate an image signal based on the first and the second output signals, and wherein the signal processor is configured to generate the image data based on the image signal.

### BRIEF DESCRIPTION OF DRAWINGS

The above and other objects and features of the present disclosure will become apparent by describing in detail embodiments thereof with reference to the accompanying drawings.

FIG. 1 is a block diagram of an electronic device according to an embodiment of the present disclosure.

FIG. 2 is a block diagram illustrating the image sensor of FIG. 1 according to some embodiments of the present disclosure.

FIG. 3 is a diagram illustrating the pixel array of FIG. 2 according to some embodiments of the present disclosure.

FIG. 4 is a diagram illustrating an example pixel arrangement of the pixel array of FIG. 2 according to some embodiments of the present disclosure.

FIG. 5 is a diagram illustrating the pixels of FIG. 4 according to some embodiments of the present disclosure.

FIG. 6 is a diagram illustrating an image sensor according to some embodiments of the present disclosure.

FIG. 7 is a flowchart illustrating a method of operating an image sensor according to some embodiments of the present disclosure.

FIG. 8 is a diagram illustrating an example of the signals of FIG. 7 according to some embodiments of the present disclosure.

FIG. 9 is a diagram illustrating sub-pixels corresponding to the signal of FIG. 7 according to some embodiments of the present disclosure.

FIG. 10 is a diagram illustrating a method of generating the image signal of FIG. 7 according to some embodiments of the present disclosure.

FIG. 11 is a flowchart illustrating a method of operating an image sensor according to some embodiments of the present disclosure.

FIG. 12 is a diagram illustrating an example pixel arrangement of a pixel array of the image sensor of FIG. 11 according to some embodiments of the present disclosure.

FIG. 13 is a diagram illustrating an example pixel arrangement of a pixel array of the image sensor of FIG. 11 according to some embodiments of the present disclosure.

FIG. 14 is a diagram illustrating an example pixel arrangement of a pixel array of the image sensor of FIG. 11 according to some embodiments of the present disclosure.

FIG. 15 is a diagram illustrating an example pixel arrangement of a pixel array of the image sensor of FIG. 11 according to some embodiments of the present disclosure.

FIG. 16 is a diagram illustrating an example pixel arrangement of a pixel array of the image sensor of FIG. 11 according to some embodiments of the present disclosure.

FIG. 17 is a diagram illustrating an example pixel arrangement of a pixel array of the image sensor of FIG. 11 according to some embodiments of the present disclosure.

FIG. 18 is a diagram illustrating an electronic device according to some embodiments of the present disclosure.

### DETAILED DESCRIPTION

Below, embodiments of the present disclosure will be described in detail and clearly to such an extent that one skilled in the art carries out embodiments of the present disclosure easily.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

As used herein, components described as being “electrically connected” are configured such that an electrical signal can be transferred from one component to the other (although such electrical signal may be attenuated in strength as it is transferred and may be selectively transferred).

It will be understood that when an element is referred to as being "connected" or "coupled" to or “on” another element, it can be directly connected or coupled to or on the other element or intervening elements may be present. In contrast, when an element is referred to as being "directly connected," "directly attached," "directly joined," or "directly coupled" to another element, or as “contacting” or “in contact with” another element (or using any form of the word “contact”), there are no intervening elements present at the point of contact. Further, in the specification, the word “on” may refer to positioning above, to the side or below an object, and does not necessarily mean positioned on the upper side of the object.

As used herein, each of the phrases such as “A or B”, “at least one of A or B”, “at least one of A or B”, “at least one of A, B, or C”, “at least one of A, B, and C”, and “at least one of B or C”, including the claims, may include any one of items listed together in the corresponding phrase, or all possible combinations thereof.

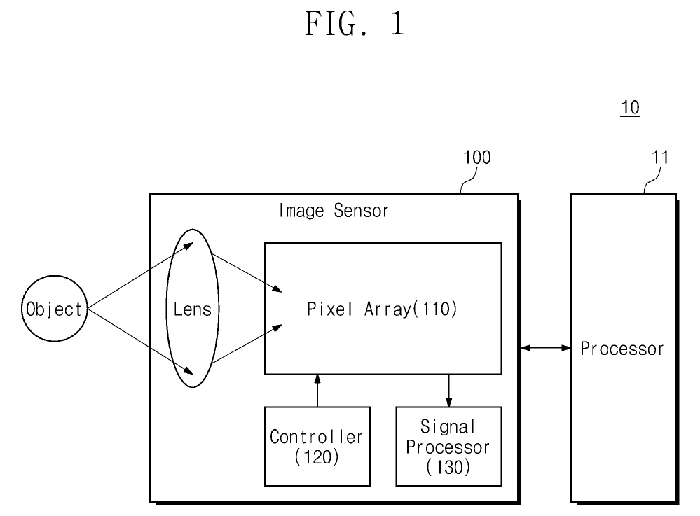

FIG. 1 is a block diagram of an electronic device according to an embodiment of the present disclosure. Referring to FIG. 1, the electronic device 10 may be an electronic system configured to process various information or store the processed information as data. For example, the electronic device 10 may be implemented as a computing system configured to process the various information, and the electronic device 10 may be a personal computer (PC), a desktop, a laptop, a server, a workstation, a tablet PC, a smartphone, a digital camera, a black box, and the like.

The electronic device 10 may include a processor 11 and an image sensor 100. The processor 11 may control various operations of the electronic device 10. The processor 11 may also be referred to as a main processor of the electronic device 10. For example, when the electronic device 10 is implemented as a mobile device, the processor 11 may be implemented as an application processor. As another example, when the electronic device 10 is implemented as a PC, a desktop, a laptop, or the like, the processor 11 may be implemented as a central processing unit (CPU), a graphics processing unit (GPU), a neural processing unit (NPU), or the like.

The image sensor 100 may receive light corresponding to an external scene (e.g., environment) that may include an object (e.g., a visual environment external to the image sensor 100). The image sensor 100 may be controlled by the processor 11, may generate an electrical signal based on the received light, and may process the electrical signal to generate image data. The image sensor 100 may provide the image data to the processor 11.

The image sensor 100 may include a lens, a pixel array 110, a controller 120, and a signal processor 130. A physical position of the lens may be adjusted by a lens driver. A focus of an image sensed by the image sensor 100 may be determined based on the physical position of the lens. The lens may be provided separately from microlenses corresponding to pixels or sub-pixels of the pixel array 110.

The pixel array 110 may be arranged adjacent to the lens. The pixel array 110 may generate the electrical signal based on the light received through the lens, and the pixel array 110 may be controlled by the controller 120.

The controller 120 may control various operations of the image sensor 100 under the control of the processor 11. The controller 120 may control sub-components of the image sensor 100. The controller 120 may also be referred to as a timing controller.

The signal processor 130 may generate the image data based on the electrical signal generated in the pixel array 110. The image data may include information indicating the external scene sensed by the image sensor 100. The signal processor 130 may support a phase detection auto-focus (PDAF) operation. The PDAF operation may be an operation for performing an auto-focus based on a phase difference value of at least two images. The signal processor 130 may communicate with the processor 11. The signal processor 130 may provide the image data to the processor 11.

The processor 11 may visually display the external scene corresponding to the image data through a display device (not illustrated). A quality of the displayed external scene by the display device may depend on various factors, such as a pixel resolution of the pixel array 110, illumination environment corresponding to an intensity of the light sensed by the image sensor 100, the focus based on the physical position of the lens, and the like.

According to embodiments of the present disclosure, by providing a circuit arrangement of the pixels or the sub-pixels of the pixel array 110, an arrangement of connected wire lines of the pixel array 100, and a method of operating the pixel array 110, various functions or operations such as high resolution, wide illumination range, auto-focus, and the like of the image sensor 100 may be provided.

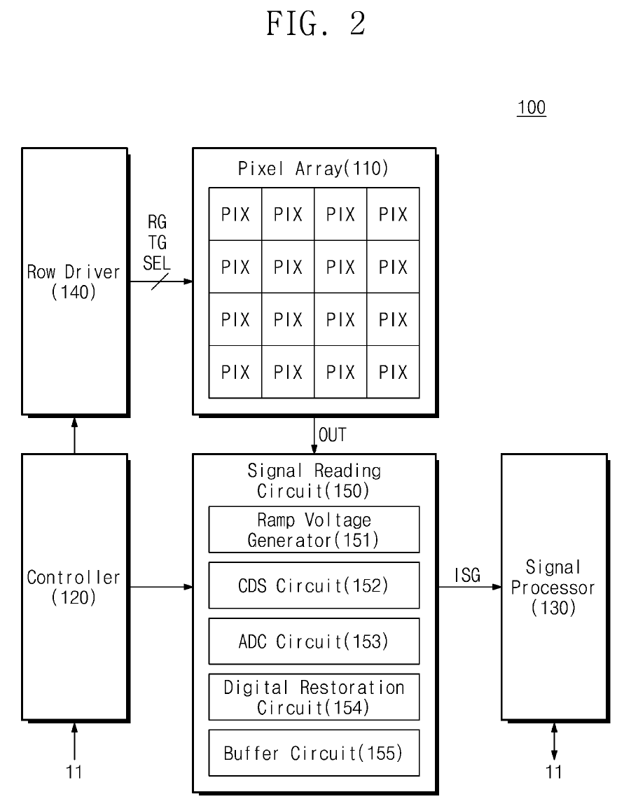

FIG. 2 is a block diagram illustrating the image sensor of FIG. 1 according to some embodiments of the present disclosure. Referring to FIGS. 1 and 2, the image sensor 100 may include the pixel array 110, the controller 120, the signal processor 130, a row driver 140, and a signal reading circuit 150. The image sensor 100 may communicate with the processor 11.

The pixel array 110 may include a plurality of pixels PIX arranged in a row direction and a column direction. The pixel PIX may include at least one photodiode. The photodiode may receive the light corresponding to the external scene and generate the electrical signal based on the photoelectric conversion operation.

For example, the pixel PIX may include one photodiode and one floating diffusion node, or the pixel PIX may include a plurality of photodiodes, or the pixel PIX may include a plurality of sub-pixels sharing a floating diffusion node.

The controller 120 may be controlled by the processor 11. The controller 120 may be connected to the row driver 140, and may control the row driver 140. The controller 120 may be connected to the signal reading circuit 150, and may control the signal reading circuit 150.

The row driver 140 may generate a reset gate signal RG, a transfer gate signal TG, and a selection signal SEL under the control of the controller 120. The reset gate signal RG may control a reset transistor of the pixel PIX. The transfer gate signal TG may control a transfer transistor of the pixel PIX. The selection signal SEL may control a selection transistor of the pixel PIX.

The pixel PIX may receive the light corresponding to the external scene including the object, and generate an output signal OUT based on the reset gate signal RG, the transfer gate signal TG, and the selection signal SEL. The output signal OUT may indicate information of the light corresponding to the external scene sensed by the pixel PIX. The output signal OUT may be a signal in an analog domain. The output signal OUT may also be referred to as a pixel output signal.

The signal reading circuit 150 may be controlled by the controller 120. The signal reading circuit 150 may be connected to the pixel array 110 and may receive at least one output signal OUT from the pixel array 110. The signal reading circuit 150 may generate an image signal ISG based on the at least one output signal OUT. The image signal ISG may be indicative of the external scene sensed by the pixel array 110. The image signal ISG may be a signal in a digital domain.

The signal reading circuit 150 may include a ramp voltage generator 151, a correlated double sampling (CDS) circuit 152, an analog-to-digital converter (ADC) circuit 153, a digital restoration circuit 154, and a buffer circuit 155.

The ramp voltage generator 151 may generate a ramp voltage under the control of the controller 120. The ramp voltage may have a voltage level that linearly changes over time within a specific time period. The ramp voltage may also be referred to as a ramp signal.

The CDS circuit 152 may be connected to the ramp voltage generator 151 and may receive the ramp voltage from the ramp voltage generator 151. The CDS circuit 152 may receive the at least one output signal OUT from the pixel array 110. The CDS circuit 152 may generate a sampled signal by performing a CDS operation based on the ramp voltage and the at least one output signal OUT. The CDS operation may include a first sampling operation of a reset voltage level and a second sampling operation of a signal voltage level indicating a sum of the reset voltage and a voltage corresponding to the sensed light. The sampled signal may be generated based on a difference in intermediate signals obtained by the first and second sampling operations. The sampled signal may be robust to noise.

The ADC circuit 153 may be connected to the CDS circuit 152 and may receive the sampled signal from the CDS circuit 152. The ADC circuit 153 may generate a digital signal by performing ADC conversion based on the sampled signal.

The digital restoration circuit 154 may be connected to the ADC circuit 153 and may receive the digital signal from the ADC circuit 153. The digital restoration circuit 154 may generate the image signal ISG based on the digital signal. For example, when a bit value indicated by the digital signal indicates a saturation state of the light, the digital restoration circuit 154 may generate the image signal ISG using another corresponding digital signal.

The buffer circuit 155 may be connected to the ADC circuit 153 and the digital restoration circuit 154, and may temporarily store the digital signal generated by the ADC circuit 153 or the image signal ISG generated by the digital restoration circuit 154. The buffer circuit 155 may also be referred to as a memory circuit or a latch circuit.

The signal processor 130 may be connected to the signal reading circuit 150 and may receive the image signal ISG from the signal reading circuit 150. For example, the signal processor 130 may receive the image signal ISG from the digital restoration circuit 154, or read the image signal ISG stored in the buffer circuit 155. The signal processor 130 may generate the image data by performing an image signal processing operation based on the image signal ISG. The signal processor 130 may provide the image data to the processor 11.

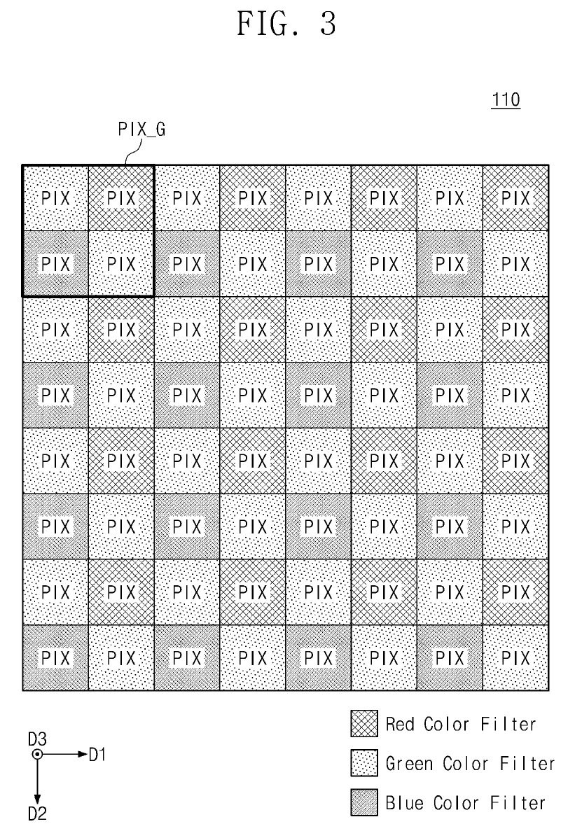

FIG. 3 is a diagram illustrating the pixel array of FIG. 2 according to some embodiments of the present disclosure. Referring to FIG. 3, the pixel array 110 may include the plurality of pixels PIX.

Hereinafter, for convenience of description, a first direction D1, a second direction D2, and a third direction D3 are referred to, and are illustrated with the coordinate axis of FIG. 3 that indicates the relative directions of the first direction D1, the second direction D2, and the third direction D3. The first direction D1 may be parallel to a transmission line to which the transfer gate signal TG is provided. The first direction D1 may also be referred to as a row direction or a horizontal direction, and a plurality of pixels PIX may be arranged along the first direction D1 (e.g., in a direction parallel to the first direction D1). The second direction D2 may be perpendicular to the first direction D1. The second direction D2 may also be referred to as a column direction or a vertical direction, a plurality of pixels PIX may be arranged along the second direction D2 (e.g., in a direction parallel to the second direction D2). The third direction D3 may be perpendicular to a plane defined by the first direction D1 and the second direction D2, with the third direction D3 perpendicular to the first direction D1 and the second direction D2. The third direction D3 may also be referred to as a height direction.

The pixel array 110 may include the plurality of pixels PIX arranged in the first direction D1 and the second direction D2. The number of the illustrated pixels PIX is merely an example, and the number of the pixels PIX arranged in the first direction D1 and the second direction D2 may be increased or decreased. A color filter may be arranged adjacent to the pixel PIX in the third direction D3. The color filter may have a color type corresponding to one of a first-color, a second-color, and a third-color. For example, the color type of the color filter may be a red type, a green type, or a blue type.

A red color filter may refer to a color filter of the red type. The red color filter may pass light of a wavelength band of the red type to a corresponding pixel PIX, and block light of another wavelength band. Similarly, a green color filter may refer to a color filter of the green type, and may pass light of a wavelength band of the green type while blocking light of other non-green wavelength bands. A blue color filter may refer to a color filter of the blue type, and may pass light of a wavelength band of the blue type while blocking light of other non-blue wavelength bands.

Four pixels PIX adjacent in the first direction D1 and the second direction D2 may be referred to as a pixel group PIX_G. For example, in the pixel group PIX_G, a green color filter may be arranged on a pixel PIX of a first row and a first column, a red color filter may be arranged on a pixel PIX of the first row and a second column, a blue color filter may be provided on a pixel PIX of a second row and the first column, and another green color filter may be provided on a pixel PIX of the second row and the second column. The first row and the second row may be parallel to, and adjacent to, each other and may extend in a direction parallel to the first direction D1. The first column and the second column may be parallel to, and adjacent to, each other and may extend in a direction parallel to the second direction D2.

In order to facilitate an understanding of the present disclosure, any four pixels PIX may be referred to as the pixel group PIX_G, but the criteria for grouping the pixel group PIX_G may be variously modified. For example, any four pixels PIX may be grouped such that the red color filter may be arranged at the first row and the first column of that respective pixel group PIX_G, or the blue color filter may be arranged at the first row and the first column of that respective pixel group PIX_G, or the positions of the red color filter and the blue color filter may be swapped with each other.

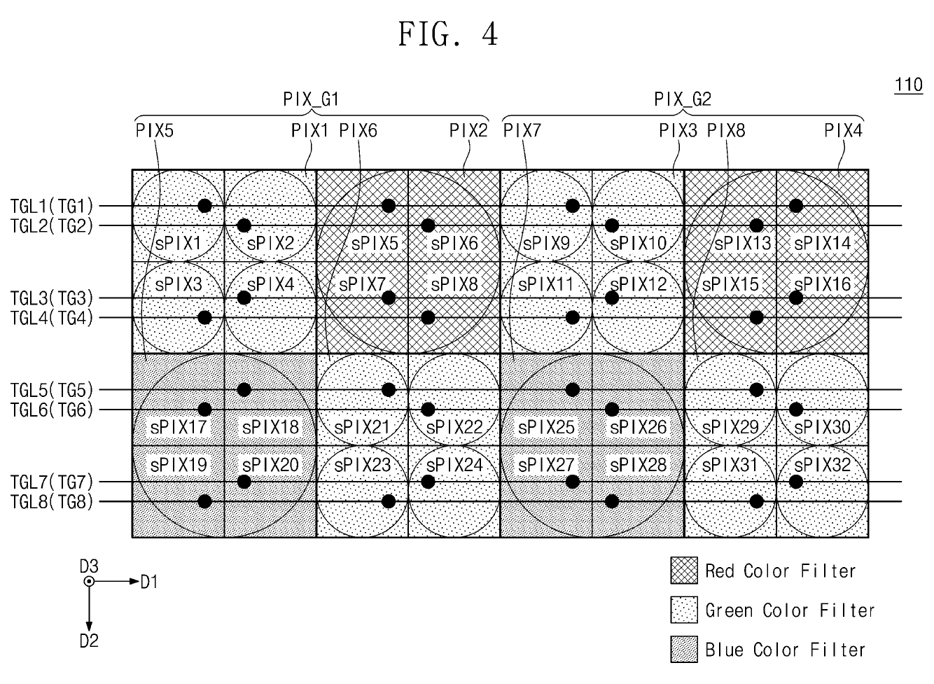

FIG. 4 is a diagram illustrating an example pixel arrangement of the pixel array of FIG. 2 according to some embodiments of the present disclosure. Referring to FIG. 4, the pixel array 110 may receive first to eighth transfer gate signals TG1-TG8 via first to eighth transmission lines TGL1-TGL8 from the row driver 140 of FIG. 2. For example, the first to eighth transmission lines TGL1-TGL8 may be connected to the row driver 140 such that signals can be transferred between the first to eighth transmission lines TGL1-TGL8 and the row driver 140.

The pixel array 110 may include a first pixel group PIX_G1 and a second pixel group PIX_G2. The second pixel group PIX_G2 may be arranged adjacent to the first pixel group PIX_G1 in the first direction D1. The first pixel group PIX_G1 may include first, second, fifth, and sixth pixels PIX1, PIX2, PIX5, and PIX6. The first, second, sixth, and fifth pixels PIX1, PIX2, PIX6, and PIX5 may be arranged in a clockwise direction. The second pixel group PIX_G2 may include third, fourth, seventh, and eighth pixels PIX3, PIX4, PIX7, and PIX8. The color types of the color filters arranged on the third, fourth, seventh, and eighth pixels PIX3, PIX4, PIX7, and PIX8 may be the same as the color types of the color filters arranged on the first, second, fifth, and sixth pixels PIX1, PIX2, PIX5, and PIX6, respectively. For example, the first, third, sixth, and eighth pixels PIX1, PIX3, PIX6, and PIX8 may have color filters of the same color type (e.g., a green color filter), while the second and fourth pixels PIX2 and PIX4 may have color filters of the same color type (e.g., a red color filter), and the fifth and seventh pixels PIX5 and PIX7 may have color filters of the same color type (e.g., a blue color filter).

In the first pixel group PIX_G1, the second pixel PIX2 may be adjacent to the first pixel PIX1 in the first direction D1. The fifth pixel PIX5 may be adjacent to the first pixel PIX1 in the second direction D2. The sixth pixel PIX6 may be adjacent to the fifth pixel PIX5 in the first direction D1. The first and sixth pixels PIX1 and PIX6 may correspond to the green type. The second pixel PIX2 may correspond to the red type. The fifth pixel PIX5 may correspond to the blue type.

In the second pixel group PIX_G2, the fourth pixel PIX4 may be adjacent to the third pixel PIX3 in the first direction D1. The seventh pixel PIX7 may be adjacent to the third pixel PIX3 in the second direction D2. The eighth pixel PIX8 may be adjacent to the seventh pixel PIX7 in the first direction D1. The third and eighth pixels PIX3 and PIX8 may correspond to the green type. The fourth pixel PIX4 may correspond to the red type. The seventh pixel PIX7 may correspond to the blue type.

The first pixel PIX1 may include first to fourth sub-pixels sPIX1-sPIX4 arranged in the first direction D1 and the second direction D2. The second sub-pixel sPIX2 may be adjacent to the first sub-pixel sPIX1 in the first direction D1. The third sub-pixel sPIX3 may be adjacent to the first sub-pixel sPIX1 in the second direction D2. The fourth sub-pixel sPIX4 may be adjacent to the third sub-pixel sPIX3 in the first direction D1.

The first to fourth sub-pixels sPIX1-sPIX4 of the first pixel PIX1 may include first to fourth photodiodes, respectively. Green color filter and four microlenses may be arranged adjacent to the first to fourth photodiodes in the third direction D3. The first to fourth photodiodes may share the green color filter. Each of the first to fourth photodiodes may each use a corresponding one of the four microlenses. Accordingly, the first photodiode of the first sub-pixel sPIX1 may use a first microlens, the second photodiode of the second sub-pixel sPIX2 may use a second microlens, the third photodiode of the third sub-pixel sPIX3 may use a third microlens, and the fourth photodiode of the fourth sub-pixel sPIX3 may use a fourth microlens. The first pixel PIX1 may also be referred to as having a ‘tetra pattern’.

The second pixel PIX2 may include fifth to eighth sub-pixels sPIX5-sPIX8 arranged in the first direction D1 and the second direction D2. The sixth sub- pixel sPIX6 may be adjacent to the fifth sub-pixel sPIX5 in the first direction D1. The seventh sub-pixel sPIX7 may be adjacent to the fifth sub-pixel sPIX5 in the second direction D2. The eighth sub-pixel sPIX8 may be adjacent to the seventh sub-pixel sPIX7 in the first direction D1.

The fifth to eighth sub-pixels sPIX5-sPIX8 of the second pixel PIX2 may include fifth to eighth photodiodes, respectively. Red color filter and a microlens may be arranged adjacent to the fifth to eighth photodiodes in the third direction D3. The fifth to eighth photodiodes may share the red color filter. The fifth to eighth photodiodes may share one microlens. The second pixel PIX2 may also be referred to as having a ‘Q-cell pattern’.

The third pixel PIX3 may include ninth to twelfth sub-pixels sPIX9-sPIX12. The ninth to twelfth sub-pixels sPIX9-sPIX12 may be respectively arranged at positions corresponding to the first to fourth sub-pixels sPIX1-sPIX4 of the first pixel PIX1. For example, the ninth sub-pixel sPIX9 and the tenth sub-pixel sPIX10 may be arranged adjacent to one another in an identical arrangement and position as the first sub-pixel sPIX1 and the second sub-pixel sPIX2. Likewise, the eleventh sub-pixel sPIX11 and the twelfth sub-pixel sPIX12 may be arranged adjacent to one another in an identical arrangement and position as the third sub-pixel sPIX3 and the fourth sub-pixel sPIX4.

The ninth to twelfth sub-pixels sPIX9-sPIX12 of the third pixel PIX3 may include ninth to twelfth photodiodes, respectively. Similar to the first to fourth sub-pixels sPIX1-sPIX4 of the first pixel PIX1, the ninth to twelfth sub-pixels sPIX9-sPIX12 may share a green color filter. Each of the ninth to twelfth sub-pixels sPIX9-sPIX12 may each use a corresponding one of the four microlens. Accordingly, the ninth photodiode of the ninth sub-pixel sPIX9 may use a ninth microlens, the tenth photodiode of the tenth sub-pixel sPIX10 may use a tenth microlens, the eleventh photodiode of the eleventh sub-pixel sPIX11 may use an eleventh microlens, and the twelfth photodiode of the twelfth sub-pixel sPIX12 may use a twelfth microlens. The third pixel PIX3 may also be referred to as having the ‘tetra pattern’.

The fourth pixel PIX4 may include thirteenth to sixteenth sub-pixels sPIX13-sPIX16. The thirteenth to sixteenth sub-pixels sPIX13-sPIX16 may be respectively arranged at positions corresponding to the fifth to eighth sub-pixels sPIX5-sPIX8 of the second pixel PIX2.

The thirteenth to sixteenth sub-pixels sPIX13-sPIX16 of the fourth pixel PIX4 may include thirteenth to sixteenth photodiodes, respectively. Similar to the fifth to eighth sub-pixels sPIX5-sPIX8 of the second pixel PIX2, the thirteenth to sixteenth sub-pixels sPIX13-sPIX16 may share a red color filter. The thirteenth to sixteenth sub-pixels sPIX13-sPIX16 may share one microlens. The fourth pixel PIX4 may also be referred to as having the ‘Q-cell pattern’.

The first to fourth transmission lines TGL1-TGL4 may be used to control the first to fourth pixels PIX1-PIX4. The first transmission line TGL1 may be electrically connected to the first, fifth, ninth, and fourteenth sub-pixels sPIX1, sPIX5, sPIX9, and sPIX14, and the first transmission line TGL1 may provide the first transfer gate signal TG1 to the first, fifth, ninth, and fourteenth sub-pixels sPIX1, sPIX5, sPIX9, and sPIX14. The second transmission line TGL2 may be electrically connected to the second, sixth, tenth, and thirteenth sub-pixels sPIX2, sPIX6, sPIX10, and sPIX13 and may provide the second transfer gate signal TG2 to the second, sixth, tenth, and thirteenth sub-pixels sPIX2, sPIX6, sPIX10, and sPIX13. The third transmission line TGL3 may be electrically connected to the fourth, seventh, twelfth, and sixteenth sub-pixels sPIX4, sPIX7, sPIX12, and sPIX16 and may provide the third transfer gate signal TG3 to the fourth, seventh, twelfth, and sixteenth sub-pixels sPIX4, sPIX7, sPIX12, and sPIX16. The fourth transmission line TGL4 may be electrically connected to the third, eighth, eleventh, and fifteenth sub-pixels sPIX3, sPIX8, sPIX11, and sPIX15 and may provide the fourth transfer gate signal TG4 to the third, eighth, eleventh, and fifteenth sub-pixels sPIX3, sPIX8, sPIX11, and sPIX15.

Contact points of the first to fourth transmission lines TGL1-TGL4 may be complementarily arranged in the second and fourth pixels PIX2 and PIX4 having the Q-cell pattern. A contact point may refer to a point at which a transmission line and a sub-pixel are electrically connected. For example, referring to the first and third transmission lines TGL1 and TGL3, contact points of the second pixel PIX2 may be located in the fifth and seventh sub-pixels sPIX5 and sPIX7 corresponding to the first column (or left). For example, the first transmission line TGL1 may contact, and may be electrically connected to, the fifth sub-pixel sPIX5, and the third transmission line TGL3 may contact, and may be electrically connected to, the seventh sub-pixel sPIX7. In addition, contact points of the fourth pixel PIX4 may be located in a fourteenth and sixteenth sub-pixels sPIX14 and sPIX16 corresponding to the second column (or right), the first transmission line TGL1 may contact, and may be electrically connected to, the fourteenth sub-pixel sPIX14, and the third transmission line TGL3 may contact, and may be electrically connected to, the sixteenth sub-pixel sPIX16.

The fifth pixel PIX5 may include seventeenth to twentieth sub-pixels sPIX17-sPIX20 arranged in the first direction D1 and the second direction D2. The eighteenth sub-pixel sPIX18 may be adjacent to the seventeenth sub-pixel sPIX17 in the first direction D1. The nineteenth sub-pixel sPIX19 may be adjacent to the seventeenth sub-pixel sPIX17 in the second direction D2. The twentieth sub-pixel sPIX20 may be adjacent to the nineteenth sub-pixel sPIX19 in the first direction D1.

The seventeenth to twentieth sub-pixels sPIX17-sPIX20 of the fifth pixel PIX5 may include seventeenth to twentieth photodiodes, respectively. A blue color filter and a microlens may be arranged adjacent to the seventeenth to twentieth photodiodes in the third direction D3. The seventeenth to twentieth photodiodes may share the blue color filter. The seventeenth to twentieth photodiodes may share one microlens. The fifth pixel PIX5 may also be referred to as having the ‘Q-cell pattern’.

The sixth pixel PIX6 may include twenty-first to twenty-fourth sub-pixels sPIX21-sPIX24. The sixth pixel PIX6 may have the tetra pattern. Each of the twenty-first to twenty-fourth sub-pixels sPIX21-sPIX24 may share a green color filter, and may each use a corresponding one of the four microlens. Accordingly, the twenty-first sub-pixel sPIX21 may use a first microlens, the twenty-second sub-pixel sPIX22 may use a second microlens, the twenty-third sub-pixel sPIX23 may use a third microlens, and the twenty-fourth sub-pixel sPIX24 may use a fourth microlens. A layout and structure of the sixth pixel PIX6 is similar to a layout and structure of the first pixel PIX1, and thus a detailed description thereof is omitted.

The seventh pixel PIX7 may include twenty-fifth to twenty-eighth sub-pixels sPIX25-sPIX28. The twenty-fifth to twenty-eighth sub-pixels sPIX25-sPIX28 may be arranged at positions corresponding to the seventeenth to twentieth sub-pixels sPIX17-sPIX20 of the fifth pixel PIX5, respectively.

The twenty-fifth to twenty-eighth sub-pixels sPIX25-sPIX28 of the seventh pixel PIX7 may include twenty-fifth to twenty-eighth photodiodes, respectively. Similar to the seventeenth to twentieth sub-pixels sPIX17-sPIX20 of the fifth pixel PIX5, the twenty-fifth to twenty-eighth sub-pixels sPIX25-sPIX28 may share a blue color filter. The twenty-fifth to twenty-eighth sub-pixels sPIX25-sPIX28 may share one microlens. The seventh pixel PIX7 may also be referred to as having the ‘Q-cell pattern’.

The eighth pixel PIX8 may include twenty-ninth to thirty-second sub-pixels sPIX29-sPIX32. The twenty-ninth to thirty-second sub-pixels sPIX29-sPIX32 may be arranged at positions corresponding to the twenty-first to twenty-fourth sub-pixels sPIX21-sPIX24 of the sixth pixel PIX6, respectively. Each of the twenty-ninth to thirty-second sub-pixels sPIX29-sPIX32 may share a green color filter, and may each use one microlens. A layout and structure of the eighth pixel PIX8 is similar to a layout and structure of the sixth pixel PIX6, and thus a detailed description thereof is omitted.

The fifth to eighth transmission lines TGL5-TGL8 may be used to control the fifth to eighth pixels PIX5-PIX8. The fifth transmission line TGL5 may be electrically connected (e.g., at respective contact points) to the eighteenth, twenty-first, twenty-fifth, and twenty-ninth sub-pixels sPIX18, sPIX21, sPIX25, and sPIX29, and the fifth transmission line TGL5 may provide the fifth transfer gate signal TG5 to the eighteenth, twenty-first, twenty-fifth, and twenty-ninth sub-pixels sPIX18, sPIX21, sPIX25, and sPIX29. The sixth transmission line TGL6 may be electrically connected (e.g., at respective contact points) to the seventeenth, twenty-second, twenty-sixth, and thirtieth sub-pixels sPIX17, sPIX22, sPIX26, and sPIX30 and may provide the sixth transfer gate signal TG6 to the seventeenth, twenty-second, twenty-sixth, and thirtieth sub-pixels sPIX17, sPIX22, sPIX26, and sPIX30. The seventh transmission line TGL7 may be electrically connected to the twentieth, twenty-fourth, twenty-seventh, and thirty-second sub-pixels sPIX20, sPIX24, sPIX27, and sPIX32 and may provide the seventh transfer gate signal TG7 to the twentieth, twenty-fourth, twenty-seventh, and thirty-second sub-pixels sPIX20, sPIX24, sPIX27, and sPIX32. The eighth transmission line TGL8 may be electrically connected to the nineteenth, twenty-third, twenty-eighth, and thirty-first sub-pixels sPIX19, sPIX23, sPIX28, and sPIX31 and may provide the eighth transfer gate signal TG8 to the nineteenth, twenty-third, twenty-eighth, and thirty-first sub-pixels sPIX19, sPIX23, sPIX28, and sPIX31.

Contact points of the fifth to eighth transmission lines TGL5-TGL8 may be complementarily arranged in the fifth and seventh pixels PIX5 and PIX7 having the Q-cell pattern. For example, referring to the sixth and eighth transmission lines TGL6 and TGL8, contact points of the fifth pixel PIX5 may be located in the seventeenth and nineteenth sub-pixels sPIX17 and sPIX19 corresponding to the first column (or left). For example, the sixth transmission line TGL6 may contact, and may be electrically connected to, the seventeenth sub-pixel sPIX17, and the eighth transmission line TGL8 may contact, and may be electrically connected to, the nineteenth sub-pixel sPIX19. In addition, contact points of the seventh pixel PIX7 may be located in the twenty-sixth and twenty-eighth sub-pixels sPIX26 and sPIX28 corresponding to the second column (or right). For example, the sixth transmission line TGL6 may contact, and may be electrically connected to, the twenty-sixth sub-pixel sPIX26, and the eighth transmission line TGL8 may contact, and may be electrically connected to, the twenty-eighth sub-pixel sPIX28.

In some embodiments, the first and second pixel groups PIX_G1, PIX_G2 may also be referred to as having a ‘Chroma Q (CQ)-cell pattern’. The CQ-cell pattern may refer to a mixture of the Q-cell pattern and the tetra pattern. For example, in the first pixel group PIX_G1 and the second pixel group PIX_G2, the first and third pixels PIX1 and PIX3 corresponding to the green color filter may have the tetra pattern, and the second and fourth pixels PIX2 and PIX4 corresponding to the red color filter or the blue color filter may have the Q-cell pattern. The first pixel group PIX_G1 may be referred to as having the CQ-cell pattern.

With regard to the first pixel group PIX_G1 having the CQ-cell pattern, by arranging the pixels corresponding to the green color filter in the tetra pattern, high resolution of green color may be provided. In addition, by arranging pixels corresponding to a red color filter or a blue color filter in the Q-cell pattern, an auto-focus operation based on a phase difference of sub-pixels sharing a microlens may be provided.

As described above, according to embodiments of the present disclosure, the contact points of adjacent pixel groups sharing the transmission line may be complementarily arranged. For example, when the first and second pixel groups are adjacent, and the positions of all contact points in the first pixel group are the same as the positions of all the contact points in the second pixel group, very bright light may be sensed in a sub-pixel in a specific direction depending on the focus state or assembly state of the lens, and if the object (or subject) is sufficiently bright in a high-illumination environment, the light sensed in the sub-pixel in the specific direction (e.g., left or right direction) may be saturated. In this case, a PDAF operation for detecting a focus state by comparing an image of a left sub-pixel and an image of a right sub-pixel and for performing a focus adjustment based on the detected focus state may be limited.

On the other hand, according to embodiments of the present disclosure, phase distortion of a restored image in the high-illumination environment is suppressed by complementarily arranging the contact points of the adjacent pixel groups sharing the transmission line, and the image sensor that performs the PDAF operation in the high-illumination environment may function to independently read out a left phase image and a right phase image.

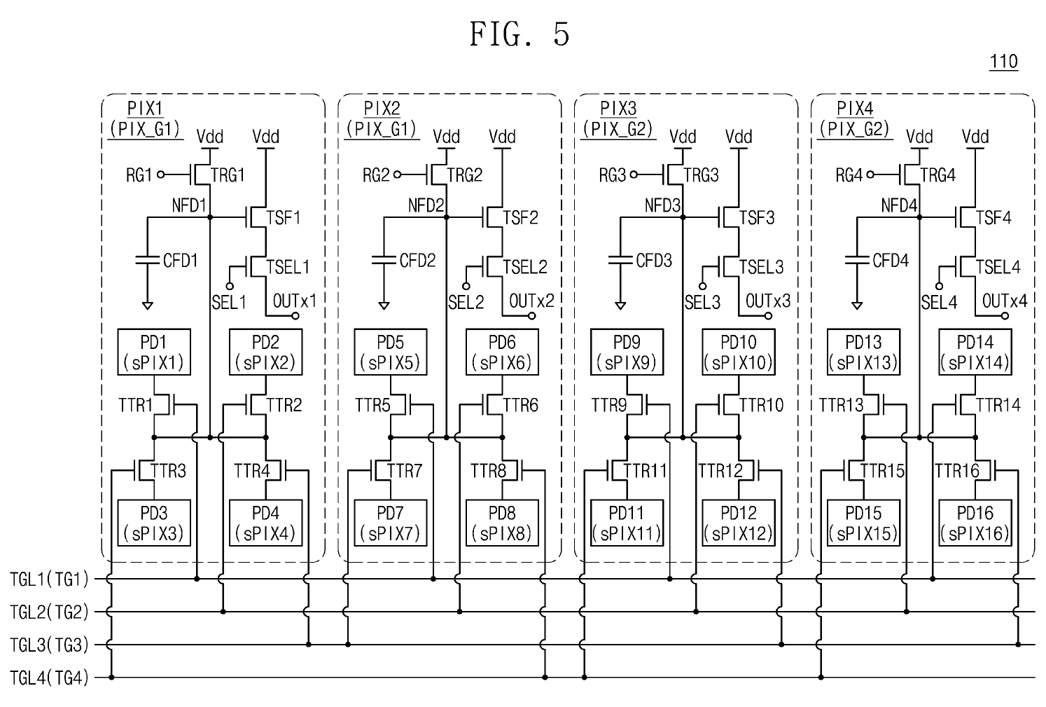

FIG. 5 is a diagram illustrating the pixels of FIG. 4 according to some embodiments of the present disclosure. Referring to FIG. 5, the pixel array 110 may include the first pixel group PIX_G1 and the second pixel group PIX_G2. The first pixel group PIX_G1 may include the first and second pixels PIX1 and PIX2. The second pixel group PIX_G2 may include the third and fourth pixels PIX3 and PIX4. The first to fourth pixels PIX1, PIX2, PIX3, and PIX4 may be electrically connected to the first to fourth transmission lines TGL1-TGL4. The first to fourth transmission lines TGL1-TGL4 may provide first to fourth transfer gate signals TG1-TG4, respectively, to the first to fourth pixels PIX1, PIX2, PIX3, and PIX4.

The first pixel PIX1 may include first to fourth photodiodes PD1-PD4, first to fourth transfer transistors TTR1-TTR4, a first capacitor CFD1, a first reset transistor TRG1, a first source follower transistor TSF1, and a first selection transistor TSEL1.

The first to fourth photodiodes PD1-PD4 may correspond to the first to fourth sub-pixels sPIX1-sPIX4, respectively. The first to fourth transfer transistors TTR1-TTR4 may be connected between a corresponding one of the first to fourth photodiodes PD1-PD4, respectively, and a first floating diffusion node NFD1. For example, the first transfer transistor TTR1 may be connected between the first photodiode PD1 and the first floating diffusion node NFD1. The other transfer transistors TTR2, TTR3, TTR4 and respective photodiodes PD2, PD3, PD4 may be connected in a similar manner. The first to fourth transfer transistors TTR1-TTR4 may operate in response to the first, second, fourth, and third transfer gate signals TG1, TG2, TG4, and TG3, respectively. For example, the first transfer transistor TTR1 may be connected to the first transmission line TGL1 to receive the first transfer gate signal TG1, the second transfer transistor TTR2 may be connected to the second transmission line TGL2 to receive the second transfer gate signal TG2, the third transfer transistor TTR3 may be connected to the fourth transmission line TGL4 to receive the fourth transfer gate signal TG4, and the fourth transfer transistor TTR4 may be connected to the third transmission line TGL3 to receive the third transfer gate signal TG3.

The first floating diffusion node NFD1 may accumulate electrons received from at least some of the first to fourth transfer transistors TTR1-TTR4. A voltage level of the accumulated electrons in the first floating diffusion node NFD1 may correspond to accumulated electrons of the first capacitor CFD1. The first capacitor CFD1 may be implemented as a parasitic capacitor or a physical capacitor.

The first reset transistor TRG1 may be connected between a power supply line provided with a power supply voltage Vdd and the first floating diffusion node NFD1. The first reset transistor TRG1 may operate in response to a first reset gate signal RG1. The first reset gate signal RG1 may be received by the first reset transistor TRG1 from the row driver 140 of FIG. 2.

The first source follower transistor TSF1 may be connected between the power supply line provided with the power supply voltage Vdd and the first selection transistor TSEL1. The first source follower transistor TSF1 may operate in response to a voltage level of the first floating diffusion node NFD1.

The first selection transistor TSEL1 may be connected between the first source follower transistor TSF1 and a first output node from which a first output signal OUTx1 is generated. The first selection transistor TSEL1 may operate in response to a first selection signal SEL1. The first selection signal SEL1 may be received by the first selection transistor TSEL1 from the row driver 140 of FIG. 2. The first output signal OUTx1 may be provided to the signal reading circuit 150 of FIG. 2.

The second pixel PIX2 may include fifth to eighth photodiodes PD5-PD8, fifth to eighth transfer transistors TTR5-TTR8, a second capacitor CFD2, a second reset transistor TRG2, a second source follower transistor TSF2, and a second selection transistor TSEL2.

The fifth to eighth photodiodes PD5-PD8 may correspond to the fifth to eighth sub-pixels sPIX5-sPIX8, respectively. The fifth to eighth transfer transistors TTR5-TTR8 may be connected to the fifth to eighth photodiodes PD5-PD8, respectively. For example, the fifth transfer transistor TTR5 may be connected between the fifth photodiode PD5 and a second floating diffusion node NFD2. The other transfer transistors TTR6, TTR7, TTR8 and respective photodiodes PD6, PD7, PD8 may be connected in a similar manner. The fifth to eighth transfer transistors TTR5-TTR8 may operate in response to the first, second, third, and fourth transfer gate signals TG1, TG2, TG3, and TG4, respectively. For example, the fifth transfer transistor TTR5 may be connected to the first transmission line TGL1 to receive the first transfer gate signal TGb, the sixth transfer transistor TTR6 may be connected to the second transmission line TGL2 to receive the second transfer gate signal TG2, the seventh transfer transistor TTR7 may be connected to the third transmission line TGL3 to receive the third transfer gate signal TG3, and the eighth transfer transistor TTR8 may be connected to the fourth transmission line TGL4 to receive the fourth transfer gate signal TG4.

The second reset transistor TRG2 may operate in response to a second reset gate signal RG2. The second source follower transistor TSF2 may operate in response to a voltage level of the second floating diffusion node NFD2. The second selection transistor TSEL2 may operate in response to a second selection signal SEL2 and generate a second output signal OUTx2 at a second output node.

The third pixel PIX3 may include ninth to twelfth photodiodes PD9-PD12, ninth to twelfth transfer transistors TTR9-TTR12, a third capacitor CFD3, a third reset transistor TRG3, a third source follower transistor TSF3, and a third selection transistor TSEL3.

The ninth to twelfth photodiodes PD9-PD12 may correspond to the ninth to twelfth sub-pixels sPIX9-sPIX12, respectively. The ninth to twelfth transfer transistors TTR9-TTR12 may be connected to the ninth to twelfth photodiodes PD9-PD12, respectively. For example, the ninth transfer transistor TTR9 may be connected between the ninth photodiode PD9 and a third floating diffusion node NFD3. The other transfer transistors TTR10, TTR11, TTR12 and respective photodiodes PD10, PD11, PD12 may be connected in a similar manner. The ninth to twelfth transfer transistors TTR9-TTR12 may operate in response to the first, second, fourth, and third transfer gate signals TG1, TG2, TG4, and TG3, respectively. For example, the ninth transfer transistor TTR9 may be connected to the first transmission line TGL1 to receive the first transfer gate signal TG1, the tenth transfer transistor TTR10 may be connected to the second transmission line TGL2 to receive the second transfer gate signal TG2, the eleventh transfer transistor TTR11 may be connected to the fourth transmission line TGL4 to receive the fourth transfer gate signal TG4, and the twelfth transfer transistor TTR12 may be connected to the third transmission line TGL3 to receive the third transfer gate signal TG3.

The third reset transistor TRG3 may operate in response to a third reset gate signal RG3. The third source follower transistor TSF3 may operate in response to a voltage level of the third floating diffusion node NFD3. The third selection transistor TSEL3 may operate in response to a third selection signal SEL3 and generate a third output signal OUTx3 at a third output node.

The fourth pixel PIX4 may include thirteenth to sixteenth photodiodes PD13-PD16, thirteenth to sixteenth transfer transistors TTR13-TTR16, a fourth capacitor CFD4, a fourth reset transistor TRG4, a fourth source follower transistor TSF4, and a fourth selection transistor TSEL4.

The thirteenth to sixteenth photodiodes PD13-PD16 may correspond to the thirteenth to sixteenth sub-pixels sPIX13-sPIX16, respectively. The thirteenth to sixteenth transfer transistors TTR13-TTR16 may be connected to the thirteenth to sixteenth photodiodes PD13-PD16, respectively. For example, the thirteenth transfer transistor TTR13 may be connected between the thirteenth photodiode PD13 and a fourth floating diffusion node NFD4. The other transfer transistors TTR14, TTR15, TTR16 and respective photodiodes PD14, PD15, PD16 may be connected in a similar manner. The thirteenth to sixteenth transfer transistors TTR13-TTR16 may operate in response to the second, first, fourth, and third transfer gate signals TG2, TG1, TG4, and TG3, respectively. For example, the thirteenth transfer transistor TTR13 may be connected to the second transmission line TGL2 to receive the second transfer gate signal TG2, the fourteenth transfer transistor TTR14 may be connected to the first transmission line TGL1 to receive the first transfer gate signal TG1, the fifteenth transfer transistor TTR15 may be connected to the fourth transmission line TGL4 to receive the fourth transfer gate signal TG4, and the sixteenth transfer transistor TTR16 may be connected to the third transmission line TGL3 to receive the third transfer gate signal TG3.

The fourth reset transistor TRG4 may operate in response to a fourth reset gate signal RG4. The fourth source follower transistor TSF4 may operate in response to a voltage level of the fourth floating diffusion node NFD4. The fourth selection transistor TSEL4 may operate in response to a fourth selection signal SEL4 and generate a fourth output signal OUTx4 at a fourth output node.

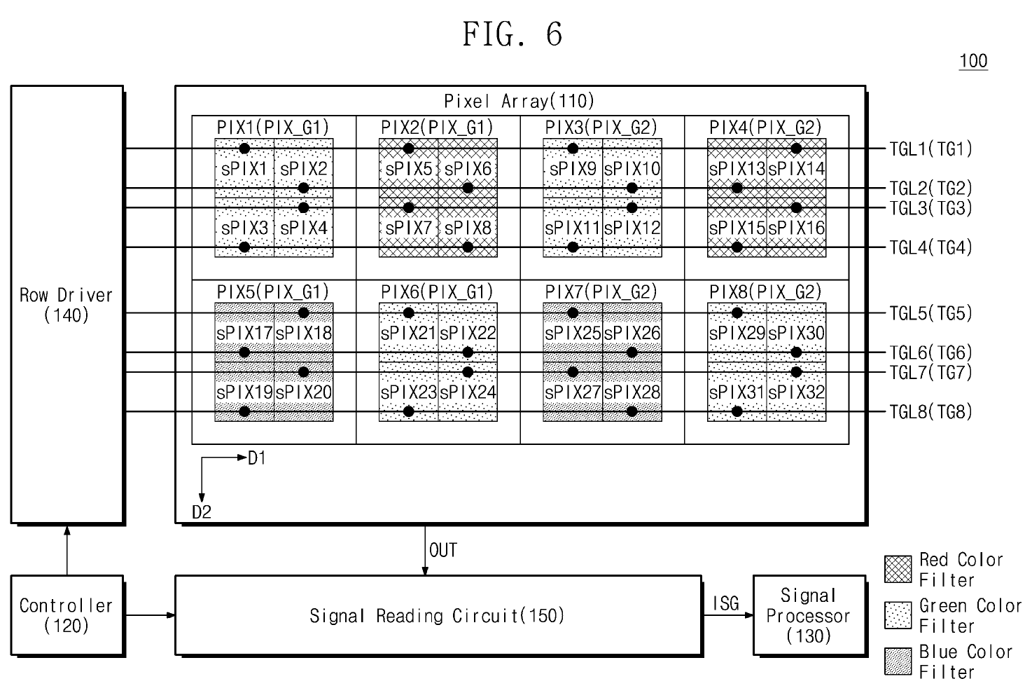

FIG. 6 is a diagram illustrating an image sensor according to some embodiments of the present disclosure. Referring to FIG. 6, the image sensor 100 may include the pixel array 110, the controller 120, the signal processor 130, the row driver 140, and the signal reading circuit 150.

The pixel array 110 may provide an output signal OUT to the signal reading circuit 150 under the control of the row driver 140. The pixel array 110 may include first and second pixel groups PIX_G1 and PIX_G2. The first pixel group PIX_G1 may include the first, second, fifth, and sixth pixels PIX1, PIX2, PIX5, and PIX6 arranged in the first and second directions D1 and D2. The second pixel group PIX_G2 may include third, fourth, seventh, and eighth pixels PIX3, PIX4, PIX7, and PIX8 arranged in the first and second directions D1 and D2.

The first pixel PIX1 may include the first to fourth sub-pixels sPIX1-sPIX4 arranged in the first and second directions D1 and D2. The second pixel PIX2 may include the fifth to eighth sub-pixels sPIX5-sPIX8 arranged in the first and second directions D1 and D2. The third pixel PIX3 may include the ninth to twelfth sub-pixels sPIX9-sPIX12 respectively arranged at positions corresponding to the first to fourth sub-pixels sPIX1-sPIx4. The fourth pixel PIX4 may include the thirteenth to sixteenth sub-pixels sPIX13-sPIX16 respectively arranged at positions corresponding to the fifth to eighth sub-pixels sPIX5-sPIX8.

The fifth pixel PIX5 may include the seventeenth to twentieth sub-pixels sPIX17-sPIX20 arranged in the first and second directions D1 and D2. The sixth pixel PIX6 may include the twenty-first to twenty-fourth sub-pixels sPIX21-sPIX24 arranged in the first and second directions D1 and D2. The seventh pixel PIX7 may include the twenty-fifth to twenty-eighth sub-pixels sPIX25-sPIX28 respectively arranged at positions corresponding to the seventeenth to twentieth sub-pixels sPIX17-sPIX20. The eighth pixel PIX8 may include the twenty-ninth to thirty-second sub-pixels sPIX29-sPIX32 respectively arranged at positions corresponding to the twenty-first to twenty-fourth sub-pixels sPIX21-sPIX24.

The color type of the color filters arranged adjacent to the first, third, sixth, and eighth pixels PIX1, PIX3, PIX6, and PIX8 in the third direction D3 may be the green type. The color type of the color filters arranged adjacent to the second and fourth pixels PIX2 and PIX4 in the third direction D3 may be the red type. The color type of the color filters arranged adjacent to the fifth and seventh pixels PIX5 and PIX7 in the third direction D3 may be the blue type.

The controller 120 may control the row driver 140 and the signal reading circuit 150. The row driver 140 may provide the first to eighth transfer gate signals TG1-TG8 to the first to eighth transmission lines TGL1-TGL8, respectively.

The first transmission line TGL1 may be connected to the first, fifth, ninth, and fourteenth sub-pixels sPIX1, sPIX5, sPIX9, and sPIX14. The second transmission line TGL2 may be connected to the second, sixth, tenth, and thirteenth sub-pixels sPIX2, sPIX6, sPIX10, and sPIX13. The third transmission line TGL3 may be connected to the fourth, seventh, twelfth, and sixteenth sub-pixels sPIX4, sPIX7, sPIX12, and sPIX16. The fourth transmission line TGL4 may be connected to the third, eighth, eleventh, and fifteenth sub-pixels sPIX3, sPIX8, sPIX11, and sPIX15.

The fifth transmission line TGL5 may be connected to the eighteenth, twenty-first, twenty-fifth, and twenty-ninth sub-pixels sPIX18, sPIX21, sPIX25, and sPIX29. The sixth transmission line TGL6 may be connected to the seventeenth, twenty-second, twenty-sixth, and thirtieth sub-pixels sPIX17, sPIX22, sPIX26, and sPIX30. The seventh transmission line TGL7 may be connected to the twentieth, twenty-fourth, twenty-seventh, and thirty-second sub-pixels sPIX20, sPIX24, sPIX27, and sPIX32. The eighth transmission line TGL8 may be connected to the nineteenth, twenty-third, twenty-eighth, and thirty-first sub-pixels sPIX19, sPIX23, sPIX28, and sPIX31.

The signal reading circuit 150 may receive the output signal OUT from the pixel array 110. The signal reading circuit 150 may generate an image signal ISG based on the output signal OUT. The signal reading circuit 150 may provide the image signal ISG to the signal processor 130. The signal processor 130 may perform an image signal processing operation based on the image signal ISG.

In some embodiments, contact points to which adjacent pixel groups and transmission lines are connected may be complementary. For example, the adjacent first and second pixel groups PIX_G1 and PIX_G2 may respectively include second and fourth pixels PIX2 and PIX4 corresponding to a red color. The row driver 140 may be connected to the fifth, seventh, fourteenth, and sixteenth sub-pixels sPIX5, sPIX7, sPIX14, and sPIX16 via the first and third transmission lines TGL1 and TGL3. A position (e.g., a left position) of the fifth and seventh sub-pixels sPIX5 and sPIX7 in the second pixel PIX2 may be complementary to a position (e. g., a right position) of the fourteenth and sixteenth sub-pixels sPIX14 and sPIX16 in the fourth pixel PIX4.

In some embodiments, the row driver 140 may selectively control some of the sub-pixels included in the same pixel. For example, the row driver 140 may be connected to the second and fourth pixels PIX2 and PIX4 via the first to fourth transmission lines TGL1-TGL4. The row driver 140 may provide first and third transfer gate signals TG1 and TG3 to the first and third transmission lines TGL1 and TGL3. The fifth and seventh sub-pixels sPIX5 and sPIX7 of the second pixel PIX2 may generate a corresponding output signal based on the first and third transfer gate signals TG1 and TG3. The fourteenth and sixteenth sub-pixels sPIX14 and sPIX16 of the fourth pixel PIX4 may generate a corresponding output signal based on the first and third transfer gate signals TG1 and TGb.

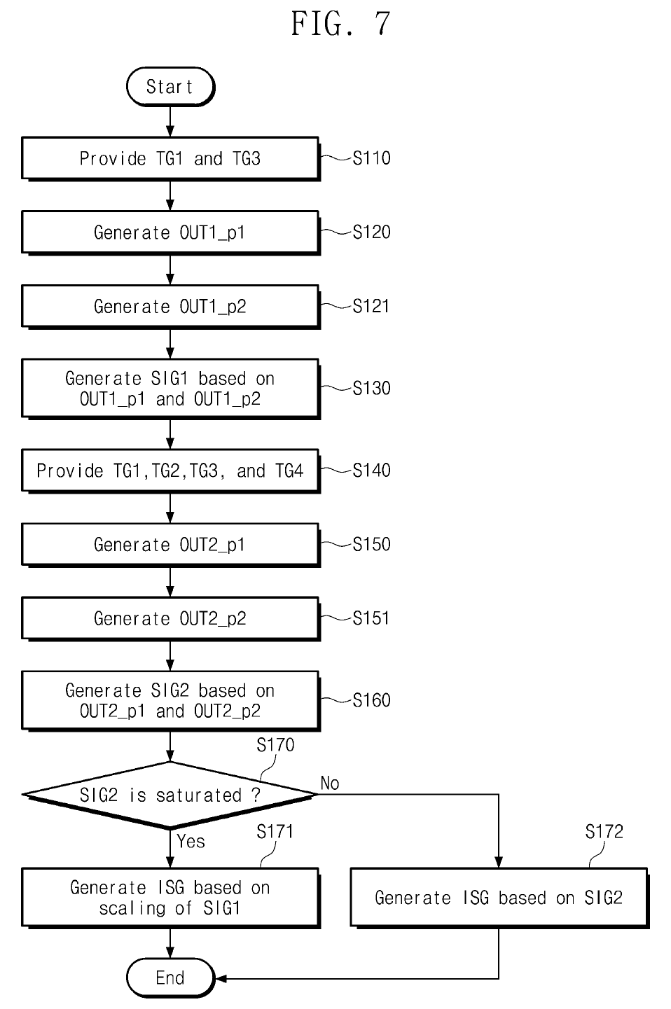

FIG. 7 is a flowchart illustrating a method of operating an image sensor according to some embodiments of the present disclosure. Referring to FIG. 7, the image sensor may include a pixel array, a row driver, and a signal reading circuit.

The pixel array may include a first pixel group and a second pixel group. The first pixel group may include a first pixel. The first pixel may include first, second, third, and fourth sub-pixels arranged in the first direction and the second direction. The second direction may be perpendicular to the first direction. The second pixel group may include a second pixel. The second pixel may include fifth, sixth, seventh, and eighth sub-pixels respectively arranged at positions corresponding to the first, second, third, and fourth sub-pixel.

For example, the first sub-pixel may be arranged in a first row and a first column within the first pixel. The second sub-pixel may be arranged in the first row and a second column within the first pixel. The third sub-pixel may be arranged in a second row and the first column within the first pixel. The fourth sub-pixel may be arranged in the second row and the second column within the first pixel.

The row driver may be connected to the first and sixth sub-pixels via a first transmission line. The row driver may be connected to the second and fifth sub-pixels via a second transmission line. The row driver may be connected to the third and eighth sub-pixels via a third transmission line. The row driver may be connected to the fourth and seventh sub-pixels via a fourth transmission line.

The signal reading circuit may receive an output signal from the pixel array, generate a signal in a digital domain based on the output signal, and generate an image signal ISG based on the signal in the digital domain.

In step S110, the row driver may provide first and third transfer gate signals TG1 and TG3 to the first and third transmission lines, respectively.

In step S120, the first pixel may generate an output signal OUT1_p1 based on the first and third transfer gate signals TG1 and TG3.

In step S121, the second pixel may generate an output signal OUT1_p2 based on the first and third transfer gate signals TG1 and TG3.

In step S130, the signal reading circuit may generate a first signal SIG1 based on the output signals OUT1_p1 and OUT1_ p2. A reset-signal-signal (RSS) readout operation sequentially includes a reading operation of a reset signal, a reading operation of a first signal, and a reading operation of a second signal. The first signal SIG1 may be the first signal of the RSS readout operation. The first signal SIG1 may be a signal in the digital domain generated by using a ramp voltage. The first signal SIG1 may indicate the intensity of light sensed by the first, third, sixth, and eighth sub-pixels generating the output signals OUT1_p1 and OUT1_ p2. In some examples, the first signal SIG1 may also be referred to as a two-sum signal corresponding to two of four sub-pixels belonging to the same pixel.

In step S140, the row driver may provide first, second, third, and fourth transfer gate signals TG1, TG2, TG3, and TG4 to the first, second, third, and fourth transmission lines, respectively.

In step S150, the first pixel may generate an output signal OUT2_p1 based on the first, second, third, and fourth transfer gate signals TG1, TG2, TG3, and TG4.

In step S151, the second pixel may generate an output signal OUT2_p2 based on the first, second, third, and fourth transfer gate signals TG1, TG2, TG3, and TG4.

In step S160, the signal reading circuit may generate a second signal SIG2 based on the output signals OUT2_p1 and OUT2_ p2. The second signal SIG2 may be the second signal of the RSS readout operation. The second signal SIG2 may be a signal in the digital domain generated by using the ramp voltage. The second signal SIG2 may indicate the intensity of light sensed by the first to eighth sub-pixels that generate the output signals OUT2_p1 and OUT2_ p2. In some examples, the second signal SIG2 may also be referred to as a four-sum signal corresponding to all of four sub-pixels belonging to the same pixel.

The first signal SIG1 and the second signal SIG2 may be used to generate the image signal ISG. For example, the signal reading circuit may generate the image signal ISG based at least in part on the first signal SIG1 and the second signal SIG2. More details of generating the image signal ISG will be described below with reference to steps S170, S171, and S172.

In step S170, the signal reading circuit may determine whether a bit value indicated by the second signal SIG2 is equal to a saturation threshold value. The saturation threshold value may correspond to a maximum intensity of light sensed by the corresponding sub-pixels. When the signal reading circuit determines that the bit value of the second signal SIG2 is equal to the saturation threshold value (for example, when the four-sum signal is saturated), the signal reading circuit may perform step S171.

In step S171, the signal reading circuit may generate the image signal ISG based on scaling of the first signal SIG1. For example, the signal reading circuit may up-scale the bit value indicated by the first signal SIG1 by two times, and generate the image signal ISG based on the up-scaled value.

Returning to step S170, when the signal reading circuit determines that the bit value of the second signal SIG2 is not equal to the saturation threshold value (e.g., when the four-sum signal is not saturated), the signal reading circuit may perform step S172.

In step S172, the signal reading circuit may generate the image signal ISG based on the second signal SIG2. For example, the signal reading circuit may generate the image signal ISG based on a bit value indicated by the second signal SIG2.

In some embodiments, the steps S170, S171, and S172 may be performed by the digital restoration circuit 154 of the signal reading circuit 150 of FIG. 2.

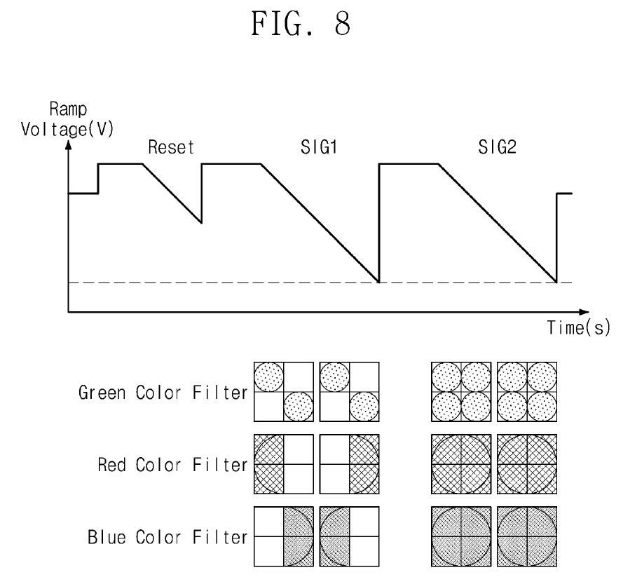

FIG. 8 is a diagram illustrating an example of the signals of FIG. 7 according to some embodiments of the present disclosure. Referring to FIGS. 7 and 8, the ramp voltage used to generate the first signal SIG1 and the second signal SIG2 is illustrated. The horizontal axis represents a time. The vertical axis represents a voltage level of the ramp voltage.

The image sensor may perform the RSS readout operation using the ramp voltage. The RSS readout operation may include reading the voltage levels of the reset signal, the first signal SIG1, and the second signal SIG2. The image sensor may read the voltage level of the reset signal of the first and second pixels before performing step S110. The reset signal may correspond to a voltage level of the floating diffusion node reset by the reset transistor. Reading a voltage level of the first signal SIG1 may correspond to steps S110, S120, S121, and S130. Reading a voltage level of the second signal SIG2 may correspond to steps S140, S150, S151, and S160.

Referring to the graph of the ramp voltage, a reset ramp waveform of the ramp voltage may be used to sense the voltage level of the reset signal. The first ramp waveform of the ramp voltage may be used to sense the voltage level of the first signal SIG1. A second ramp waveform of the ramp voltage may be used to sense the voltage level of the second signal SIG2.

In some embodiments, the image sensor may support a high dynamic range (HDR) operation. The HDR operation may refer to combining a bright image and a dark image corresponding to the same scene and using the combined images. The dark image may correspond to the first signal SIG1. The bright image may correspond to the second signal SIG2. The lowest voltage level of the first ramp waveform corresponding to the first signal SIG1 may be the same as the lowest voltage level of the second ramp waveform corresponding to a second signal SIG2. The number of bits corresponding to the first signal SIG1 may be equal to the number of bits corresponding to the second signal SIG2. A first time length for readout of the first signal SIG1 may be equal to a second time length for readout of the second signal SIG2 due to the number of bits corresponding to the first signal SIG1 being equal to the number of bits corresponding to the second signal SIG2.

The first signal SIG1 may also be referred to as the two-sum signal. When the first and second pixels correspond to a green color filter, the sub-pixels at the diagonal position (e.g., relative to the green color filter image illustrated in FIG. 8) in the first pixel and the sub-pixels at the diagonal position in the second pixel may be activated (e.g., operated in response to a transfer gate signal). When the first and second pixels correspond to a red color filter (e.g., relative to the red color filter image illustrated in FIG. 8), the left sub-pixels in the first pixel and the right sub-pixel in the second pixel may be activated. When the first and second pixels correspond to a blue color filter (e.g., relative to the blue color filter image illustrated in FIG. 8), the right sub-pixels in the first pixel and the left sub-pixel in the second pixel may be activated.

The second signal SIG2 may also be referred to as the four-sum signal. Regardless of the color type corresponding to the first and second pixels, all sub-pixels of the first and second pixels may be activated.

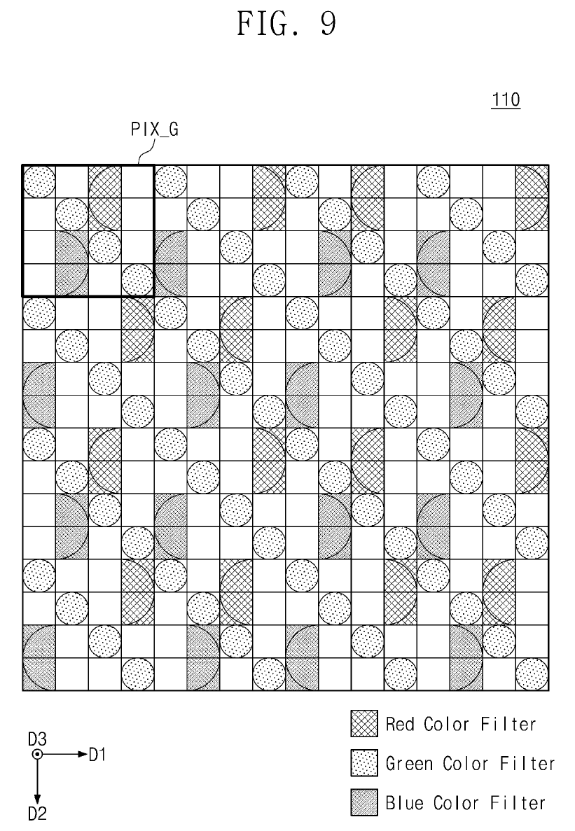

FIG. 9 is a diagram illustrating sub-pixels corresponding to the signal of FIG. 7 according to some embodiments of the present disclosure. Referring to FIGS. 7 and 9, the pixel array 110 may include a plurality of pixel groups PIX_G. The pixel groups PIX_G may have the CQ-cell pattern.

In the pixel array 110, the sub-pixels used to generate the first signal SIG1 are illustrated with shading of a corresponding color filter. The sub-pixels that do not directly contribute to the generation of the first signal SIG1 are illustrated to have no shading. Accordingly, as illustrated in FIG. 9, 50% of the sub-pixels are shaded, thus illustrating a contribution from 50% of the sub-pixels to the generation of the first signal SIG1, while 50% of the sub-pixels are not shaded, thus illustrating that 50% of the sub-pixels (e.g., represented by the non-shaded pixels) do not contribute to the generation of the first signal SIG1.

In the pixel group PIX_G, the pixel corresponding to the red color and the pixel corresponding the blue color may have the Q-cell pattern. In the readout operation of the first signal SIG1, a pixel having the Q-cell pattern in the pixel group PIX_G may be activated complementary to a corresponding pixel in another adjacent pixel group PIX_G in the first direction D1 or the second direction D2. For example, in the pixel group PIX_G highlighted in FIG. 9, the left pixels corresponding to the red color filter may be activated, while in an adjacent pixel group (e.g., in the first direction D1 or the second direction D2), the right pixels corresponding to the red color filter may be activated. In the pixel group PIX_G highlighted in FIG. 9, the right pixels corresponding to the blue color filter may be activated, while in an adjacent pixel group (e.g., in the first direction D1 or the second direction D2), the left pixels corresponding to the blue color filter may be activated. Accordingly, since the image signal ISG restored based on the first signal SIG1 (for example, step S171 in FIG. 7) may not be deflected to the left phase or the right phase of the microlens, phase distortion of the restored image in the high-illumination environment may be suppressed.

For example, the brightness of light sensed in the sub-pixels located in the left position of the microlens may be different from the brightness of light detected in the sub-pixels located in a right position. Since adjacent pixels in the present disclosure are complementary activated, the first signal SIG1 may correspond to an average of the brightness of the left position of the microlens and the brightness of the right position of the microlens.

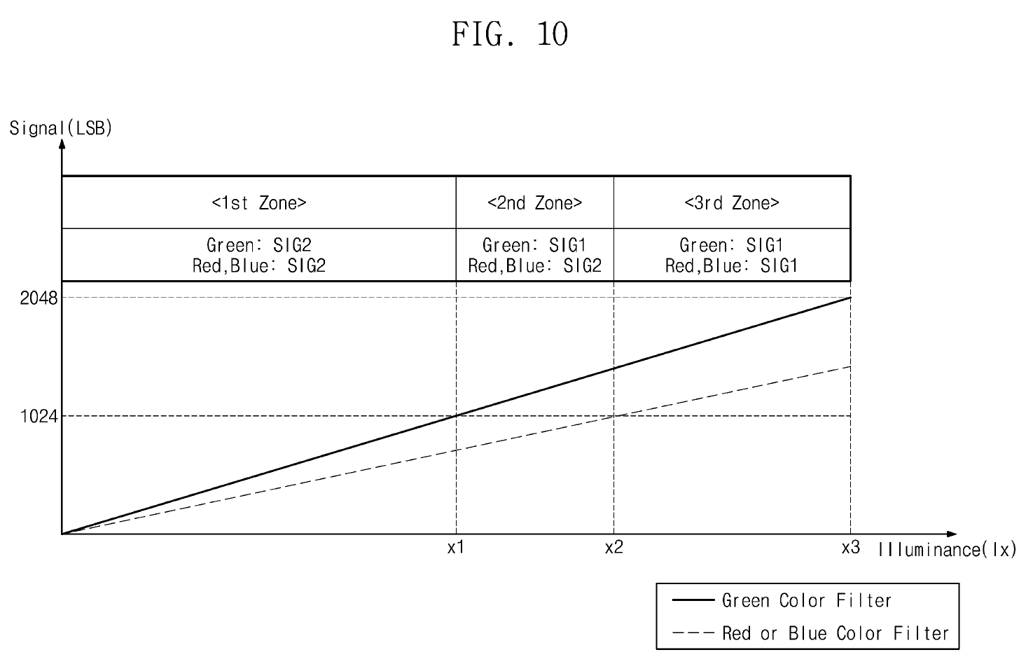

FIG. 10 is a diagram illustrating a method of generating the image signal of FIG. 7 according to some embodiments of the present disclosure. Referring to FIG. 10, a method of generating an image signal ISG according to a brightness condition is described. The horizontal axis of the graph represents brightness. The vertical axis of the graph represents a least significant bit (LSB) of the image signal ISG. To facilitate understanding of the present disclosure, it is described that each of the first and second signals SIG1 and SIG2 has a size of 10 bits, and the image signal ISG has a size of 11 bits, but the present disclosure is not necessarily limited thereto.

The first zone may refer to a brightness interval in which the intensity of light is between zero and a first brightness x1. The first brightness x1 may be a threshold brightness at which the four-sum signal corresponding to the green color is saturated. For example, a value of the four-sum signal may reach a saturation threshold value of ‘1024 (i.e., 2¹⁰)’. In the first zone, the image sensor may generate the image signal ISG based on the second signal SIG2 corresponding to the green color. The image sensor may generate the image signal ISG based on the second signal SIG2 corresponding to the red or blue color.

The second zone may refer to a brightness interval in which the intensity of light is between the first brightness x1 and a second brightness x2. The second brightness x2 may be a threshold brightness at which the four-sum signal corresponding to the red or blue color is saturated. In the second zone, the image sensor may generate the image signal ISG based on scaling of the first signal SIG1 corresponding to the green color. The image sensor may generate the image signal ISG based on the second signal SIG2 corresponding to the red or blue color.

The third zone may refer to a brightness interval in which the intensity of light is between the second brightness x2 and a third brightness x3. The third brightness x3 may be a threshold brightness at which the scaled signal is saturated based on the two-sum signal corresponding to the green color. For example, the up-scaled value of the two-sum signal corresponding to the green color by two times may reach ‘2048 (i.e., 2¹¹)’. In the third zone, the image sensor may generate the image signal ISG based on scaling of the first signal SIG1 corresponding to the green color. The image sensor may generate the image signal ISG based on scaling of the first signal SIG1 corresponding to the red or blue color.

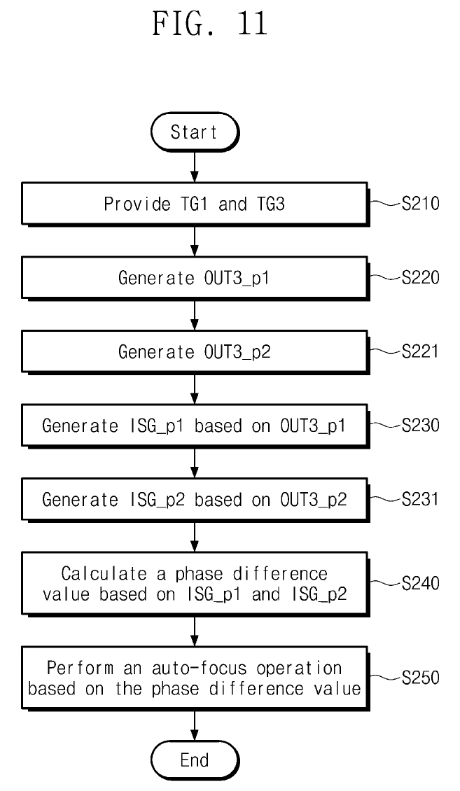

FIG. 11 is a flowchart illustrating a method of operating an image sensor according to some embodiments of the present disclosure. Referring to FIG. 11, the image sensor may include a pixel array, a row driver, a signal reading circuit, and a signal processor.

The pixel array may include a first pixel group and a second pixel group. The first pixel group may include a first pixel. The first pixel may include first, second, third, and fourth sub-pixels arranged in the first direction and the second direction. The second direction may be perpendicular to the first direction. The second pixel group may include a second pixel. The second pixel may include fifth, sixth, seventh, and eighth sub-pixels respectively arranged at positions corresponding to the first, second, third, and fourth sub-pixel.

The row driver may be connected to the first and sixth sub-pixels (e.g., corresponding to the fifth sub-pixel sPIX5 and the fourteenth sub-pixel sPIX14, respectively, of FIG. 4) via a first transmission line (e.g., the first transmission line TGL1 of FIG. 4). The row driver may be connected to the second and fifth sub-pixels (e.g., corresponding to the sixth sub-pixel sPIX6 and the thirteenth sub-pixel sPIX13, respectively, of FIG. 4) via a second transmission line (e.g., the second transmission line TGL2 of FIG. 4). The row driver may be connected to the third and eighth sub-pixels (e.g., corresponding to the seventh sub-pixel sPIX7 and the sixteenth sub-pixel sPIX16, respectively, of FIG. 4) via a third transmission line (e.g., the third transmission line TGL3 of FIG. 4). The row driver may be connected to the fourth and seventh sub-pixels (e.g., corresponding to the eighth sub-pixel sPIX8 and the fifteenth sub-pixel sPIX15, respectively, of FIG. 4) via a fourth transmission line (e.g., the third transmission line TGL4 of FIG. 4).

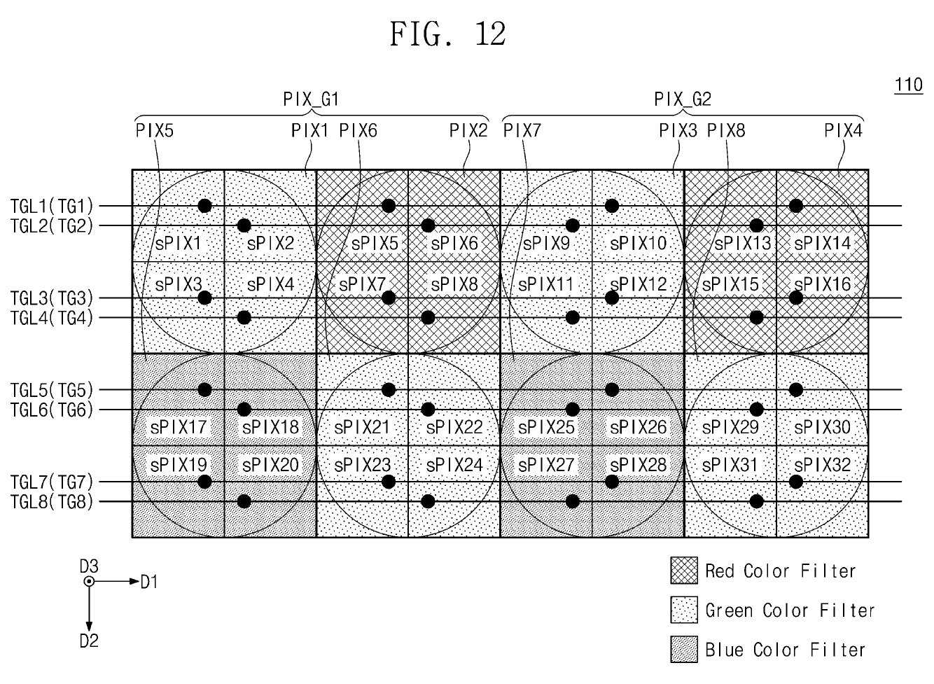

However, the present disclosure is not limited thereto, and the arrangement of the pixels and the connection arrangement of the transmission lines may be changed with reference to FIGS. 12 to 17 described below. Accordingly, the transmission lines and the pixel of steps S210, S220, and S221 may be changed.

The signal reading circuitry may receive an output signal from the pixel array, generate a signal in a digital domain based on the output signal, and generate an image signal based on the signal in the digital domain. The signal processor may perform a PDAF operation based on the image signal.

In step S210, the row driver may provide first and third transfer gate signals TG1 and TG3 to the first and third transmission lines, respectively.

In step S220, the first pixel may generate an output signal OUT3_p1 based on the first and third transfer gate signals TG1 and TG3. For example, the output signal OUT3_p1 may be generated by at least one photodiode arranged on the left side among photodiodes sharing a microlens. For example, when four photodiodes of a pixel share a microlens (e.g., relative to pixels with the red color filter or the blue color filter), the output signal OUT3_p1 may be generated by the photodiodes on the left side of the pixel.

In step S221, the second pixel may generate an output signal OUT3_p2 based on the first and third transfer gate signals TG1 and TG3. For example, the output signal OUT3_p2 may be generated by at least one photodiode arranged on the right side among photodiodes sharing a microlens. For example, when four photodiodes of a pixel share a microlens (e.g., relative to pixels with the red color filter or the blue color filter), the output signal OUT3_p1 may be generated by the photodiodes on the right side of the pixel.

In step S230, the signal reading circuit may generate a first partial image signal ISG_p1 based on the output signal OUT3_p1. In some examples, the first partial image signal ISG_p1 may represent a left phase image.

In step S231, the signal reading circuit may generate a second partial image signal ISG_p2 based on the output signal OUT3_p2. In some examples, the second partial image signal ISG_p2 may represent a right phase image. The first and second partial image signals ISG_p1, ISG_p2 may also be collectively referred to as an image signal.

In step S240, the signal processor may calculate a phase difference value based on the first and second partial image signals ISG_p1 and ISG_p2. The phase difference value may be calculated by comparing the first and second partial image signals ISG_p1 and ISG_p2. For example, in some embodiments, a cross-correlation calculation may be performed to determine the phase shift or difference between the first and second partial image signals ISG_p1 and ISG_p2. Alternatively, a phase spectrum subtraction calculation may be performed by subtracting the phase angles of the first and second partial image signals ISG_p1 and ISG_p2 to determine the phase shift or difference.

In step S250, the signal processor may perform an auto-focus operation based on the phase difference value. For example, once the phase difference value between the first and second partial image signals ISG_p1 and ISG_p2 has been calculated, the signal processor may adjust the focus (e.g., by performing the auto-focus operation) based on the magnitude of the phase difference. For example, a larger phase difference value necessitates a larger focus adjustment (e.g., of the lens position), while a smaller phase difference value necessitates a smaller focus adjustment. The phase difference value provides a direction and magnitude of the phase difference, thus facilitating the auto-focus operation.

In general, the contact points of adjacent pixel groups may be the same. The image sensor may obtain a two-sum signal as a left phase image, obtain a four-sum signal as an entire phase image, and then obtain a right phase image by subtracting the two-sum signal from the four-sum signal. When the four-sum signal is saturated, the PDAF operation may be difficult.

On the other hand, according to embodiments of the present disclosure, by complementarily arranging the contact points of adjacent pixel groups, the left phase image and the right phase image may be independently read out. For example, the complementary arrangement of the contact points is illustrated in FIG. 4, in which the first transmission line TGL1 contacts the fifth sub-pixel sPIX5 (e.g., left sub-pixel of the red color filter in a first pixel group) and contacts the fourteenth sub-pixel sPIX14 (e.g., right sub-pixel of the red color filter in an adjacent second pixel group). Even in the high-illumination environment in which the four-sum signal is saturated, the left phase image and the right phase image may be independently obtained. The image sensor may perform the PDAF operation based on the independently read left and right phase images in the high-illumination environment.

FIG. 12 is a diagram illustrating an example pixel arrangement of a pixel array of the image sensor of FIG. 11 according to some embodiments of the present disclosure. Referring to FIGS. 11 and 12, the pixel array 110 may include first and second pixel groups PIX_G1 and PIX_G2. The first and second pixel groups PIX_G1 and PIX_G2 may have the Q-cell pattern. The first and second pixel groups PIX_G1 and PIX_G2 may include first to eighth pixels PIX1-PIX8. The first to eighth pixels PIX1-PIX8 may include first to thirty-second sub-pixels sPIX1-sPIX32. The arrangement of the pixels may be similar to the arrangement illustrated and described relative to FIG. 4. However, as illustrated in FIG. 12, the contact points at which the first to eighth transmission lines TGL1-TGL8 contact the sub-pixels may differ from the example of FIG. 4. For example, in FIG. 12, the first transmission line TGL1 may contact the tenth sub-pixel sPIX10, the second transmission line TGL2 may contact the ninth sub-pixel sPIX9, the third transmission line TGL3 may contact the third sub-pixel sPIX3, the fourth transmission line TGL4 may contact the fourth sub-pixel sPIX4, the fifth transmission line TGL5 may contact the seventeenth, twenty-sixth, and thirtieth sub-pixels sPIX17, sPIX26, sPIX30, the sixth transmission line TGL6 may contact the eighteenth, twenty-fifth, and twenty-ninth sub-pixels sPIX18, sPIX25, sPIX29, the seventh transmission line TGL7 may contact the nineteenth, twenty-third, and twenty-eighth sub-pixels sPIX19, sPIX23, sPIX28, and the eighth transmission line TGL8 may contact the twentieth, twenty-fourth, and twenty-seventh sub-pixels sPIX20, sPIX24, sPIX27. Furthermore, an arrangement of microlenses may differ from the example of FIG. 4. For example, the first to fourth sub-pixels sPIX1-sPIX4 may share the microlens. The ninth to twelfth sub-pixels sPIX9-sPIX12 may share the microlens. The twenty-first to twenty-fourth sub-pixels sPIX21-sPIX24 may share the microlens. The twenty-ninth to thirty-second sub-pixels sPIX29-sPIX32 may share the microlens.

In some embodiments, the row driver may provide at least some of first, third, fifth, and seventh transfer gate signals TG1, TG3, TG5, and TG7 to at least some of first, third, fifth, and seventh transmission lines TGL1, TGL3, TGL5, and TGL7, respectively. At least some of the left sub-pixels sPIX1, sPIX3, sPIX5, sPIX7, sPIX17, sPIX19, sPIX21, and sPIX23 of the first pixel group PIX_G1 may generate the output signal OUT3_p1 in step S220. At least some of the right sub-pixels sPIX10, sPIX12, sPIX14, sPIX16, sPIX26, sPIX28, sPIX30, and sPIX32 of the second pixel group PIX_G2 may generate the output signal OUT3_p2 in step S221.

In some embodiments, the row driver may provide at least some of second, fourth, sixth, and eighth transfer gate signals TG2, TG4, TG6, and TG8 to at least some of second, fourth, sixth, and eighth transmission lines TGL2, TGL4, TGL6, and TGL8, respectively. At least some of the left sub-pixels sPIX9, sPIX11, sPIX13, sPIX15, sPIX25, sPIX27, sPIX29, and sPIX31 of the second pixel group PIX_G2 may generate the output signal OUT3_p1 in step S220. At least some of the right sub-pixels sPIX2, sPIX4, sPIX6, sPIX8, sPIX18, sPIX20, sPIX22, and sPIX24 of the first pixel group PIX_G1 may generate the output signal OUT3_p2 in step S221.

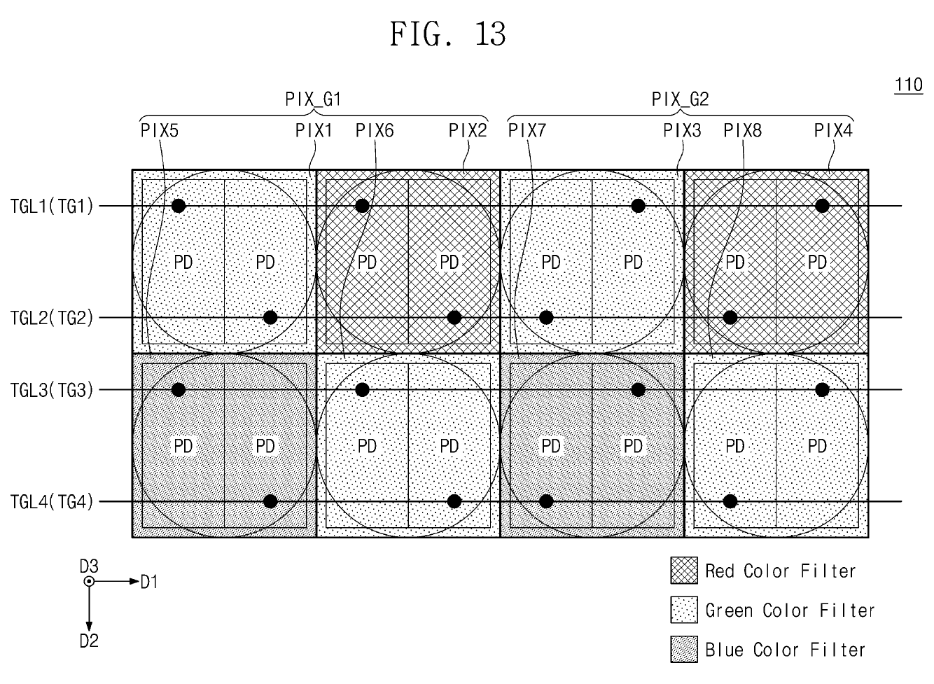

FIG. 13 is a diagram illustrating an example pixel arrangement of a pixel array of the image sensor of FIG. 11 according to some embodiments of the present disclosure. Referring to FIGS. 11 and 13, the pixel array 110 may include first and second pixel groups PIX_G1 and PIX_G2. The first and second pixel groups PIX_G1 and PIX_G2 may have a Bayer two-PD pattern. The first and second pixel groups PIX_G1 and PIX_G2 may include first to eighth pixels PIX1-PIX8. Each of the first to eighth pixels PIX1-PIX8 may include two photodiodes PD.

In some embodiments, the row driver may provide at least some of first and third transfer gate signals TG1 and TG3 to at least some of first and third transmission lines TGL1 and TGL3, respectively. At least some of the left photodiodes PD of the first pixel group PIX_G1 may generate the output signal OUT3_p1 in step S220. At least some of the right photodiodes PD of the second pixel group PIX_G2 may generate the output signal OUT3_p2 in step S221.

In some embodiments, the row driver may provide at least some of second and fourth transfer gate signals TG2 and TG4 to at least some of second and fourth transmission lines TGL2 and TGL4, respectively. At least some of the left photodiodes PD of the second pixel group PIX_G2 may generate the output signal OUT3_p1 in step S220. At least some of the right photodiodes PD of the first pixel group PIX_G1 may generate the output signal OUT3_p2 in step S221.

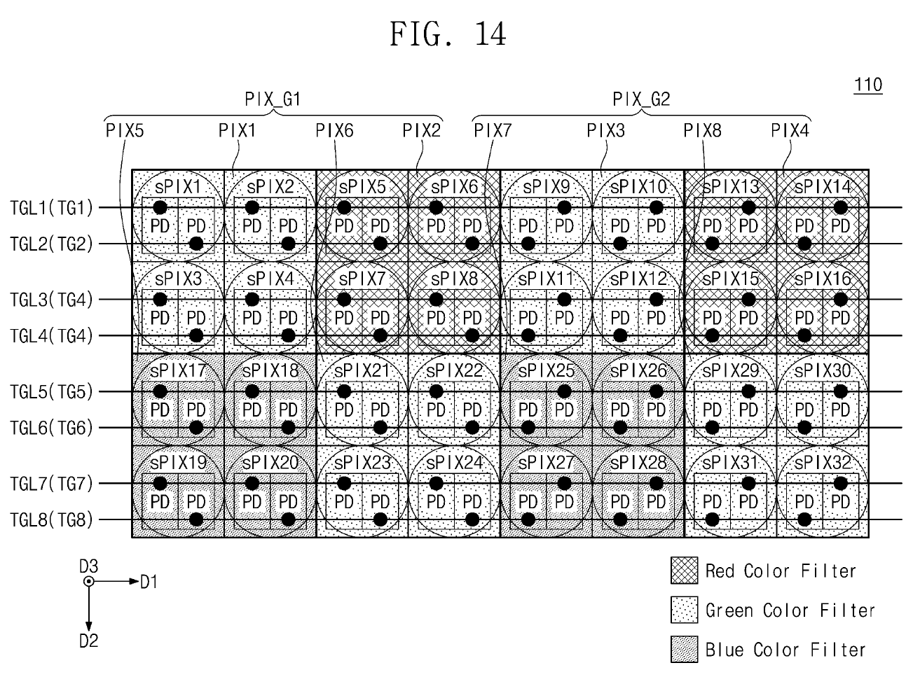

FIG. 14 is a diagram illustrating an example pixel arrangement of a pixel array of the image sensor of FIG. 11 according to some embodiments of the present disclosure. Referring to FIGS. 11 and 14, the pixel array 110 may include first and second pixel groups PIX_G1 and PIX_G2. The first and second pixel groups PIX_G1 and PIX_G2 may have a tetra two-PD pattern. The first and second pixel groups PIX_G1 and PIX_G2 may include first to eighth pixels PIX1-PIX8. The first to eighth pixels PIX1-PIX8 may include first to thirty-second sub-pixels sPIX1-sPIX32. Each of the first to thirty-second sub-pixels sPIX1-sPIX32 may include two photodiodes PD.

In some embodiments, the row driver may provide at least some of first, third, fifth, and seventh transfer gate signals TG1, TG3, TG5, and TG7 to at least some of first, third, fifth, and seventh transmission lines TGL1, TGL3, TGL5, and TGL7, respectively. At least some of the left photodiodes PD of the first pixel group PIX_G1 may generate the output signal OUT3_p1 in step S220. At least some of the right photodiodes PD of the second pixel group PIX_G2 may generate the output signal OUT3_p2 in step S221.

In some embodiments, the row driver may provide at least some of second, fourth, sixth, and eighth transfer gate signals TG2, TG4, TG6, and TG8 to at least some of second, fourth, sixth, and eighth transmission lines TGL2, TGL4, TGL6, and TGL8, respectively. At least some of the left photodiodes PD of the second pixel group PIX_G2 may generate the output signal OUT3_p1 in step S220. At least some of the right photodiodes PD of the first pixel group PIX_G1 may generate the output signal OUT3_p2 in step S221.

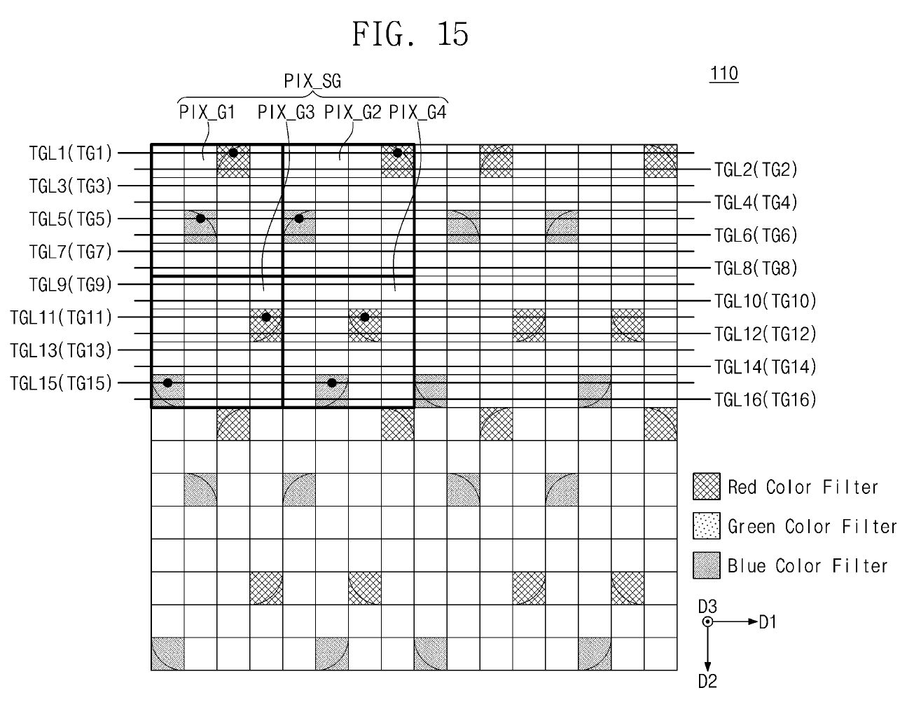

FIG. 15 is a diagram illustrating an example pixel arrangement of a pixel array of the image sensor of FIG. 11 according to some embodiments of the present disclosure. Referring to FIGS. 11 and 15, the pixel array 110 may include a super pixel group PIX_SG. The super pixel group PIX_SG may include first to fourth pixel groups PIX_G1, PIX_G2, PIX_G3, and PIX_G4. The first to fourth pixel groups PIX_G1, PIX_G2, PIX_G3, and PIX_G4 may have the CQ-cell pattern.

In some embodiments, the row driver may provide first and eleventh transfer gate signals TG1 and TG11 to the first and eleventh transmission lines TGL1 and TGL11, respectively, and the first transmission line TGL1 may be connected to the first pixel group PIX_G1 and the second pixel group PIX_G2, and the eleventh transmission line TGL11 may be connected to the third pixel group PIX_G3 and the fourth pixel group PIX_G4. The first and fourth pixel groups PIX_G1 and PIX_G4 may generate the output signal OUT3_p1 in step S220. The second and third pixel groups PIX_G2 and PIX_G3 may generate the output signal OUT3_p2 in step S221. At this time, the readout time length may be a quarter of the readout time length for the four-sum signal.

In some embodiments, the row driver may provide fifth and fifteenth transfer gate signals TG5 and TG15 to the fifth and fifteenth transmission lines TGL5 and TGL15, respectively, with the fifth transmission line TGL5 connected to the first pixel group PIX_G1 and the second pixel group PIX_G2, and the fifteenth transmission line TGL15 connected to the third pixel group PIX_G3 and the fourth pixel group PIX_G4. The second and third pixel groups PIX_G2 and PIX_G3 may generate the output signal OUT3_p1 in step S220. The first and fourth pixel groups PIX_G1 and PIX_G4 may generate the output signal OUT3_p2 in step S221. At this time, the readout time length may be a quarter of the readout time length for the four-sum signal.

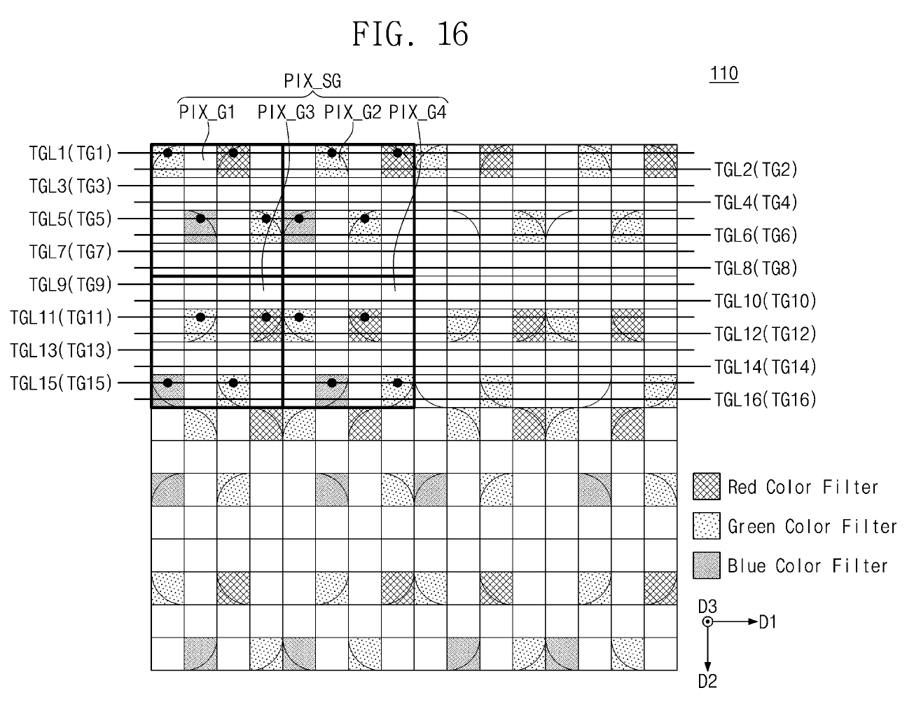

FIG. 16 is a diagram illustrating an example pixel arrangement of a pixel array of the image sensor of FIG. 11 according to some embodiments of the present disclosure. Referring to FIGS. 11 and 16, the pixel array 110 may include a super pixel group PIX_SG. The super pixel group PIX_SG may include first to fourth pixel groups PIX_G1, PIX_G2, PIX_G3, and PIX_G4. The first to fourth pixel groups PIX_G1, PIX_G2, PIX_G3, and PIX_G4 may have the Q-cell pattern. The contact points may be complementarily arranged in the first and second directions D1 and D2.

In some embodiments, the row driver may provide first and eleventh transfer gate signals TG1 and TG11 to the first and eleventh transmission lines TGL1 and TGL11, respectively, and the first transmission line TGL1 may be connected to the first pixel group PIX_G1 and the second pixel group PIX_G2, and the eleventh transmission line TGL11 may be connected to the third pixel group PIX_G3 and the fourth pixel group PIX_G4. The first and fourth pixel groups PIX_G1 and PIX_G4 may generate the output signal OUT3_p1 in step S220. The second and third pixel groups PIX_G2 and PIX_G3 may generate the output signal OUT3_p2 in step S221.

In this case, due to the first and eleventh transmission lines TGL1 and TGL11 being connected to sub-pixels corresponding to the green and red type color filter, the color type of the corresponding color filter may be the green type or the red type. The readout time length may be a quarter of the readout time length for the four-sum signal.

In some embodiments, the row driver may provide fifth and fifteenth transfer gate signals TG5 and TG15 to the fifth and fifteenth transmission lines TGL5 and TGL15, respectively, and the fifth transmission line TGL5 may be connected to the first pixel group PIX_G1 and the second pixel group PIX_G2, and the fifteenth transmission line TGL15 may be connected to the third pixel group PIX_G3 and the fourth pixel group PIX_G4. The second and third pixel groups PIX_G2 and PIX_G3 may generate the output signal OUT3_p1 in step S220. The first and fourth pixel groups PIX_G1 and PIX_G4 may generate the output signal OUT3_p2 in step S221. In this case, due to the fifth and fifteenth transmission lines TGL5 and TGL15 being connected to sub-pixels corresponding to the blue and green type color filter, the color type of the corresponding color filter may be the blue type or the green type. The readout time length may be a quarter of the readout time length for the four-sum signal.

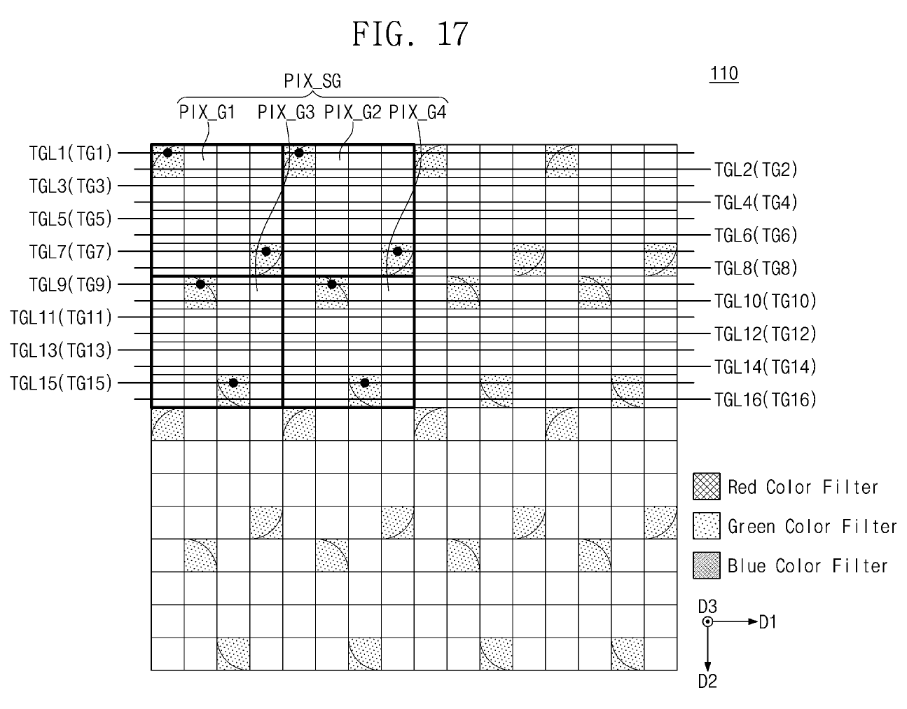

FIG. 17 is a diagram illustrating an example pixel arrangement of a pixel array of the image sensor of FIG. 11 according to some embodiments of the present disclosure. Referring to FIGS. 11 and 17, the pixel array 110 may include a super pixel group PIX_SG. The super pixel group PIX_SG may include first to fourth pixel groups PIX_G1, PIX_G2, PIX_G3, and PIX_G4. The first to fourth pixel groups PIX_G1, PIX_G2, PIX_G3, and PIX_G4 may have the Q-cell pattern. The contact points may be complementarily arranged in the second direction D2.

In some embodiments, the row driver may provide first, seventh, ninth, and fifteenth transfer gate signals TG1, TG7, TG9, and TG15 to the first, seventh, ninth, and fifteenth transmission lines TGL1, TGL7, TGL9, and GTL15, respectively. The first transmission line TGL1 may be connected to sub-pixels corresponding to the green type color filter in the first pixel group PIX_G1 and the second pixel group PIX_G2, the seventh transmission line TGL7 may be connected to sub-pixels corresponding to the green type color filter in the first pixel group PIX_G1 and the second pixel group PIX_G2, the ninth transmission line TGL9 may be connected to sub-pixels corresponding to the green type color filter in the third pixel group PIX_G3 and the fourth pixel group PIX_G4, and the fifteenth transmission line TGL15 may be connected to sub-pixels corresponding to the green type color filter in the third pixel group PIX_G3 and the fourth pixel group PIX_G4. The super pixel group PIX_SG may generate the output signal OUT3_p1 of step S220 based on the first and fifteenth transfer gate signals TG1 and TG15. The super pixel group PIX_SG may generate the output signal OUT3_p2 in step S221 based on the seventh and ninth transfer gate signals TG7 and TG9. At this time, the readout time length may be a quarter of the readout time length for the four-sum signal.

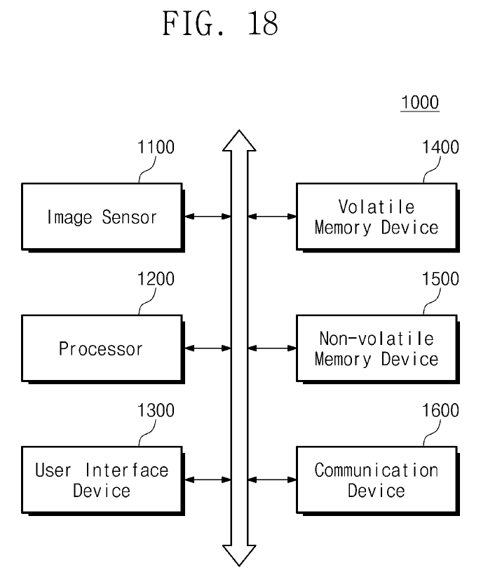

FIG. 18 is a diagram illustrating an electronic device according to some embodiments of the present disclosure. Referring to FIG. 18, the electronic device 1000 may include an image sensor 1100, a processor 1200, a user interface device 1300, a volatile memory device 1400, a non-volatile memory device 1500, and a communication device 1600. The electronic device 1000, the image sensor 1100, and the processor 1200 may correspond to the electronic device 10, the image sensor 100, and the processor 11 of FIG. 1, respectively.

The image sensor 1100 may capture the external scene and generate the image data.

The processor 1200 may control the various operations of the electronic device 1000 and manage the image data.

The user interface device 1300 may provide an interface between a user and the electronic device 1000. For example, the user interface device 1300 may be implemented as a display device, a touch screen device, a microphone, a speaker, a keyboard, a mouse, or the like.

The volatile memory device 1400 may store the image data under control of the processor 1200. The volatile memory device 1400 may operate as a main memory device or a buffer memory device of the electronic device 1000. For example, the volatile memory device 1400 may be implemented as a dynamic random access memory (DRAM), a static random access memory (SRAM), a synchronous dynamic Radom access memory (SDRAM), or the like. The volatile memory device 1400 may also be referred to as a memory device of the electronic device 1000.

The non-volatile memory device 1500 may store the image data under control of the processor 1200. The non-volatile memory device 1500 may operate as a mass storage device of the electronic device 1000. For example, the non-volatile memory device 1500 may be implemented as a Not-AND (NAND) flash memory, a Not-OR (NOR) flash memory, or the like. The non-volatile memory device 1500 may also be referred to as a memory device of the electronic device 1000.

The communication device 1600 may provide a function of wired communication or wireless communication with another external electronic device (e.g., a user terminal, a server device, a network device, or the like).

According to the embodiments of the present disclosure, the image sensor including the pixel, the method for operating the same, and the electronic device including the same are provided.

In addition, according to the embodiments of the present disclosure, the image sensor is provided in which the phase distortion of the restored image in the high-illumination environment is suppressed by complementarily arranging the contact points of the adjacent pixel groups sharing the transmission line, and the phase detection auto-focus (PDAF) operation is performed in the high-illumination environment by independently reading out the left phase image and the right phase image.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. An image sensor comprising:
a pixel array including a first pixel comprising first to fourth sub-pixels arranged in a clockwise direction and a second pixel comprising fifth to eighth sub-pixels arranged in the clockwise direction; and
a row driver configured to provide first to fourth transfer gate signals to the first to fourth sub-pixels via first to fourth transmission lines,
wherein the first to fourth sub-pixels are configured to share a first-color color filter and a first microlens,
wherein the fifth to eighth sub-pixels are configured to share a second-color color filter and a second microlens,
wherein the first-color is the same as the second-color,
wherein the first sub-pixel and the sixth sub-pixel are configured to receive the first transfer gate signal via the first transmission line,
wherein the second sub-pixel and the fifth sub-pixel are configured to receive the second transfer gate signal via the second transmission line,
wherein the third sub-pixel and the seventh sub-pixels are configured to receive the third transfer gate signal via the third transmission line, and
wherein the fourth sub-pixel and the eighth sub-pixel are configured to receive the fourth transfer gate signal via the fourth transmission line.

2. The image sensor of claim 1, further comprising:
a third pixel comprising ninth to twelfth sub-pixels arranged in the clockwise direction,
wherein the ninth to twelfth sub-pixels are configured to share a third-color color filter,
wherein the third-color is different from the first-color, and
wherein the first pixel, the third pixel, and the second pixel are sequentially arranged in a first row.

3. The image sensor of claim 2, wherein the ninth to twelfth sub-pixels are configured to share a third microlens.

4. The image sensor of claim 3, wherein the tenth sub-pixel is configured to receive the first transfer gate signal via the first transmission line.

5. The image sensor of claim 3, wherein the twelfth sub-pixel is configured to receive the fourth transfer gate signal via the fourth transmission line.

6. The image sensor of claim 2, wherein a plurality of microlens are disposed on the ninth to twelfth sub-pixels.

7. The image sensor of claim 2, wherein four microlens are disposed on the ninth to twelfth sub-pixels.

8. The image sensor of claim 6, wherein the ninth sub-pixel is configured to receive the first transfer gate signal via the first transmission line.

9. The image sensor of claim 6, wherein the tenth sub-pixel is configured to receive the second transfer gate signal via the second transmission line.

10. The image sensor of claim 6, wherein the eleventh sub-pixel is configured to receive the third transfer gate signal via the third transmission line.

11. The image sensor of claim 6, wherein the third-color is green color.

12. An image sensor comprising:
a pixel array including a first pixel comprising first and second sub-pixels and a second pixel comprising third and fourth sub-pixels; and
a row driver configured to provide first and second transfer gate signals to the first to fourth sub-pixels via first and second transmission lines,
wherein the first and second sub-pixels are configured to share a first-color color filter and a first microlens,
wherein the third and fourth sub-pixels are configured to share a second-color color filter and a second microlens,
wherein the first-color is the same as the second-color,
wherein the first sub-pixel and the fourth sub-pixel are configured to receive the first transfer gate signal via the first transmission line,
wherein the second sub-pixel and the third sub-pixel are configured to receive the second transfer gate signal via the second transmission line, and
wherein the first to fourth sub-pixels are sequentially arranged in a first row.

13. The image sensor of claim 12, further comprising:
a third pixel comprising fifth and sixth sub-pixels,
wherein the fifth and sixth sub-pixels are configured to share a third-color color filter, and a third microlens,
wherein the third-color is different from the first-color, and
wherein the first pixel, the third pixel, and the second pixel are sequentially arranged in the first row.

14. The image sensor of claim 13, wherein the fifth sub-pixel is configured to receive the first transfer gate signal via the first transmission line.

15. The image sensor of claim 13, further comprising:
a fourth pixel between the third pixel and the second pixel,
wherein the third pixel is directly adjacent to the first pixel, and
wherein the first pixel, the third pixel, the fourth pixel, and the second pixel are sequentially arranged in the first row.

16. The image sensor of claim 15, wherein the fourth pixel comprises:
seventh and eighth sub-pixels,
wherein the seventh and eighth sub-pixels are configured to share a fourth-color color filter, and a fourth microlens,
wherein the fourth-color is the same as the third-color, and
wherein the fourth pixel is directly adjacent to the third pixel.

17. The image sensor of claim 16, further comprising:
a fifth pixel comprising ninth and tenth sub-pixels,
wherein the ninth and tenth sub-pixels are configured to share a fifth-color color filter, and a fifth microlens,
wherein the fifth-color is the same as the first-color,
wherein the fifth pixel is directly adjacent to the first pixel, and
wherein the fifth pixel, the first pixel, the third pixel, the fourth pixel, and the second pixel are sequentially arranged in the first row.

18. An image sensor comprising:
a pixel array including a first pixel comprising first and second sub-pixels, a second pixel comprising third and fourth sub-pixels, and a third pixel comprising fifth and sixth sub-pixels; and
a row driver configured to provide first to third transfer gate signals to the first to fourth sub-pixels via first to third transmission lines,
wherein the first and second sub-pixels are configured to share a first green color filter and a first microlens,
wherein the third and fourth sub-pixels are configured to share a second green color filter and a second microlens,
wherein the fifth and sixth sub-pixels are configured to share a third green color filter and a third microlens,
wherein the first sub-pixel and the fourth sub-pixel are configured to receive the first transfer gate signal via the first transmission line,
wherein the second sub-pixel and the third sub-pixel are configured to receive the second transfer gate signal via the second transmission line,
wherein the first to fourth sub-pixels are sequentially arranged in a first row,
wherein the first sub-pixel is directly adjacent to the fifth sub-pixel in a first column, and
wherein each of the first sub-pixel and the fifth sub-pixel are disposed on a left side of each of the first pixel and the third pixel in a plan view.

19. The image sensor of claim 18, wherein the fifth sub-pixel is configured to receive the third transfer gate signal via the third transmission line, and
wherein the first sub-pixel and the fifth sub-pixel are configured to receive the first transfer gate signal and the third transfer gate signal simultaneously, respectively.

20. The image sensor of claim 19, wherein the first sub-pixel and the fourth sub-pixel are configured to receive the first transfer gate signal simultaneously.
